(19) United States
(12) Patent Application Publication
(10) Pub. No.: US 2025/0393362 A1
(43) Pub. Date: Dec. 25, 2025

(54) DISPLAY DEVICE

(71) Applicant: SAMSUNG ELECTRONICS CO., LTD., Suwon-si (KR)

(72) Inventors: Sanguk KIM, Suwon-si (KR); Bongjin Lee, Suwon-si (KR); Hankyu Seong, Suwon-si (KR); Sungjin Ahn, Suwon-si (KR); Jinho Lee, Suwon-si (KR)

(73) Assignee: SAMSUNG ELECTRONICS CO., LTD., Suwon-si (KR)

(21) Appl. No.: 19/024,949

(22) Filed: Jan. 16, 2025

(30) Foreign Application Priority Data
Jun. 20, 2024 (KR) 10-2024-0080589

(51) Int. Cl. H10H 29/49; H10H 29/855

(52) U.S. Cl. CPC H10H 29/49; H10H 29/855

(57) ABSTRACT

A display device includes a substrate, first, second, and third sub-pixels arranged on the substrate and separated from each other in a horizontal direction, a first wire electrically connecting the first sub-pixels to each other, a second wire electrically connecting the second sub-pixels to each other, and the first wire is electrically separated from the second wire.

### CROSS-REFERENCE TO RELATED APPLICATION

This application is based on and claims priority under 35 U.S.C. § 119 to Korean Patent Application No. 10-2024-0080589, filed on Jun. 20, 2024, in the Korean Intellectual Property Office, the disclosure of which is incorporated by reference herein in its entirety.

### BACKGROUND

### 1. Field

The disclosure relates to a display device, and more particularly, to a display device including a light-emitting element.

### 2. Description of Related Art

A light-emitting diode (LED) is a light source that converts electrical energy into optical energy, and is widely used as a light source for various display devices, such as lighting devices, televisions (TVs), mobile phones, personal computers (PCs), laptop computers, personal digital assistants (PDAs), digital cameras, camcorders, viewfinders, micro displays, three-dimensional (3D) displays, virtual reality, or augmented reality displays. Recently, micro-or nano-scale ultra-small LEDs using II-VI or III-V group compound semiconductors have been developed.

### SUMMARY

One or more embodiments may provide a display device with increased light efficiency.

Also, objects of the disclosure are not limited to the objects described above, and the other objects may be clearly understood by those skilled in the art from the description below.

According to an aspect of the disclosure, a display device may include: a substrate; first sub-pixels; second sub-pixels; third sub-pixels, wherein the first sub-pixels, the second sub-pixels, and the third sub-pixels are separated in a horizontal direction; a first wire electrically connecting the first sub-pixels; and a second wire electrically connecting the second sub-pixels, wherein the first wire is electrically separated from the second wire.

According to an aspect of the disclosure, a display device may include: a substrate; a first sub-pixel; a second sub-pixel; a third sub-pixel, wherein the first sub-pixel, the second sub-pixel, and the third sub-pixel are separated in a horizontal direction; a first conductive layer configured to receive a first voltage; a second conductive layer configured to receive a second voltage different from the first voltage; a first wire electrically connecting the first sub-pixel to the first conductive layer; and a second wire electrically connecting the second sub-pixel to the second conductive layer. The first wire may be electrically separated from the second wire, and the first conductive layer may be electrically separated from the second conductive layer.

According to an aspect of the disclosure, a display device may include: a circuit substrate including a drive circuit; and a pixel array on the circuit substrate, the pixel array may include: a first sub-pixel; a second sub-pixel; a third sub-pixel; a first conductive base semiconductor layer including a main surface and a back surface opposite to the main surface; a plurality of semiconductor light-emitting structures on the main surface of the first conductive base semiconductor layer and separated in a horizontal direction parallel to the main surface, the plurality of semiconductor light-emitting structures including a first conductive semiconductor layer, an active layer, and a second conductive semiconductor layer sequentially stacked in a vertical direction perpendicular to the main surface; a first electrode between adjacent identical sub-pixels, the first electrode including a metal layer passing through the first conductive base semiconductor layer in the vertical direction; a separation layer between the first sub-pixel and the second sub-pixel which are adjacent, the separation layer including an insulating layer passing through the first conductive base semiconductor layer in the vertical direction; a reflective structure covering sidewalls of the plurality of semiconductor light-emitting structures; a plurality of second electrodes passing through the reflective structure in the vertical direction; and a plurality of microlenses on the back surface of the first conductive base semiconductor layer and overlapping the plurality of semiconductor light-emitting structures in the vertical direction.

According to an aspect of the disclosure, a display device may include: a substrate; a first sub-pixel; a second sub-pixel adjacent to the first sub-pixel in a horizontal direction; a conductive base semiconductor layer on the substrate; a first conductive layer; a second conductive layer; a first wire electrically connecting the first sub-pixel to the first conductive layer; a second wire electrically connecting the second sub-pixel to the second conductive layer, wherein the first wire is electrically separated from the second wire; and a separation layer between the first sub-pixel and the second sub-pixel, the separation layer including an insulating layer passing through the conductive base semiconductor layer in a vertical direction.

### BRIEF DESCRIPTION OF THE DRAWINGS

Embodiments of the disclosure will be more clearly understood from the following detailed description taken in conjunction with the accompanying drawings in which:

FIG. 1 is a schematic perspective view illustrating a display device according to one or more embodiments;

FIG. 2 is a plan view illustrating a pixel region and a conductive layer according to one or more embodiments;

FIG. 3 is an enlarged plan view of a portion indicated by “EX2” of FIG. 1 according to one or more embodiments;

FIG. 4 is a cross-sectional view schematically illustrating components taken along line I-I′ of FIG. 1 and components taken along line IV-IV′ of FIG. 3 according to one or more embodiments;

FIG. 5 is a cross-sectional view schematically illustrating components taken along line II-II′ of FIG. 1 and components taken along line IV-IV′ of FIG. 3 according to one or more embodiments;

FIG. 6 is a cross-sectional view schematically illustrating components taken along line III-III′ of FIG. 1 and components taken along line IV-IV′ of FIG. 3 according to one or more embodiments;

FIG. 7 is a cross-sectional view schematically illustrating components taken along line I-I′ of FIG. 1 and components taken along line V-V′ of FIG. 3 according to one or more embodiments;

FIG. 8 is a cross-sectional view schematically illustrating components taken along line II-II′ of FIG. 1 and components taken along line VI-VI′ of FIG. 3 according to one or more embodiments;

FIG. 9 is a cross-sectional view schematically illustrating components taken along line III-III′ of FIG. 1 and components taken along line VII-VII′ of FIG. 3 according to one or more embodiments;

FIG. 10 is a cross-sectional view schematically illustrating components taken along line II-II′ of FIG. 1 and components taken along line IV-IV′ of FIG. 3 according to one or more embodiments;

FIG. 11A is a plan view illustrating a display device according to one or more embodiments;

FIG. 11B is a view schematically illustrating a region of the display device of FIG. 11A corresponding to a region A of FIG. 2 according to one or more embodiments;

FIG. 12A is a plan view illustrating a display device according to one or more embodiments;

FIG. 12B is a view schematically illustrating a region of the display device of FIG. 12A corresponding to a region A of FIG. 2 according to one or more embodiments;

FIG. 13 is an enlarged plan view of a portion corresponding to a portion indicated by “EX2” of FIG. 1 according to one or more embodiments;

FIG. 14A is a plan view illustrating a display device according to one or more embodiments;

FIG. 14B is a view schematically illustrating a region of the display device of FIG. 14A which corresponds to a region A of FIG. 2 according to one or more embodiments;

FIG. 15A is a plan view illustrating a display device according to one or more embodiments;

FIG. 15B is a view schematically illustrating a connection relationship between a plurality of sub-pixels and wires of the display device of FIG. 15A according to one or more embodiments;

FIG. 16 is a circuit diagram briefly illustrating a display device according to one or more embodiments;

FIG. 17 is a circuit diagram briefly illustrating a display device according to one or more embodiments;

FIG. 18 is a circuit diagram briefly illustrating a display device according to one or more embodiments;

FIG. 19 is a block diagram of an electronic device including a display device according to one or more embodiments;

FIG. 20 is a view illustrating one or more embodiments of a mobile device as an application example of an electronic device;

FIG. 21 is a view illustrating one or more embodiments of a head-up display device for a vehicle as an application example of an electronic device;

FIG. 22 is a view illustrating one or more embodiments of augmented reality glasses or virtual reality glasses as an application example of an electronic device;

FIG. 23 is a view illustrating one or more embodiments of a large signage as an application example of an electronic device; and

FIG. 24 is a view illustrating one or more embodiments of a wearable display as an application example of an electronic device.

### DETAILED DESCRIPTION

Hereinafter, embodiments of the disclosure are described in detail with reference to the attached drawings. The same reference numerals are used for the same components in the drawings, and redundant descriptions thereof are omitted. In the drawings below, thicknesses and sizes of respective layers are exaggerated for the sake of convenience and clarity of description, and accordingly, the thicknesses and sizes of respective layers may differ somewhat from actual shape and ratio.

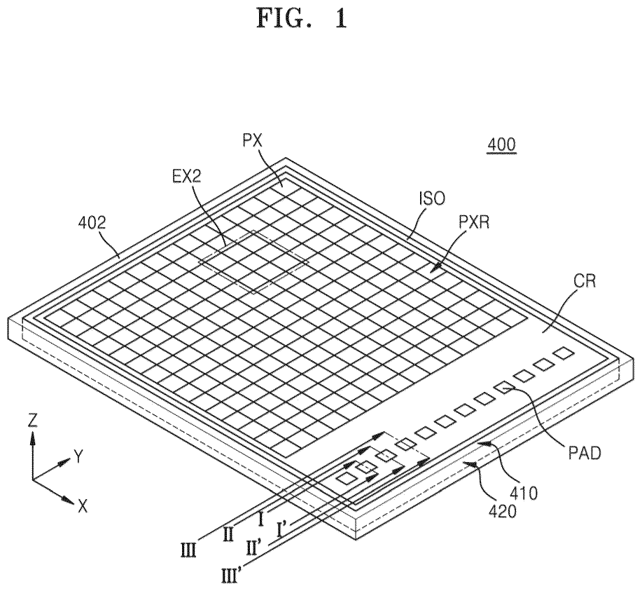

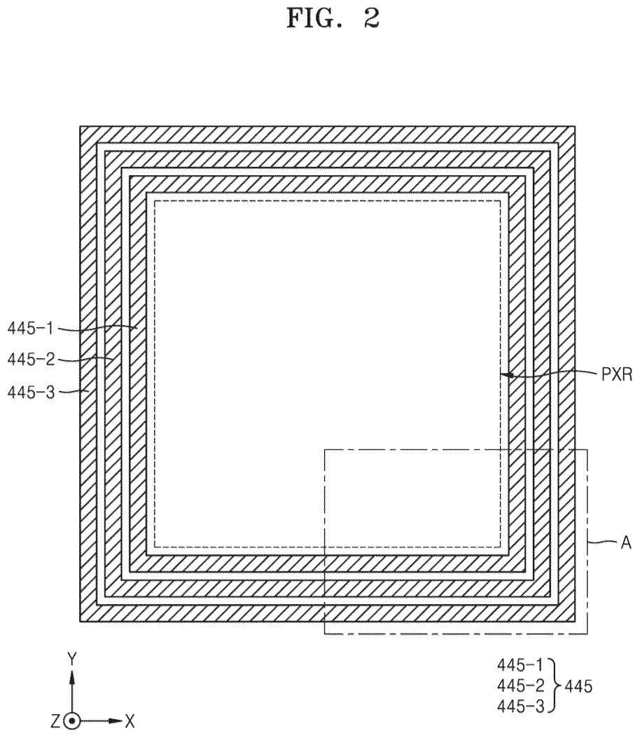

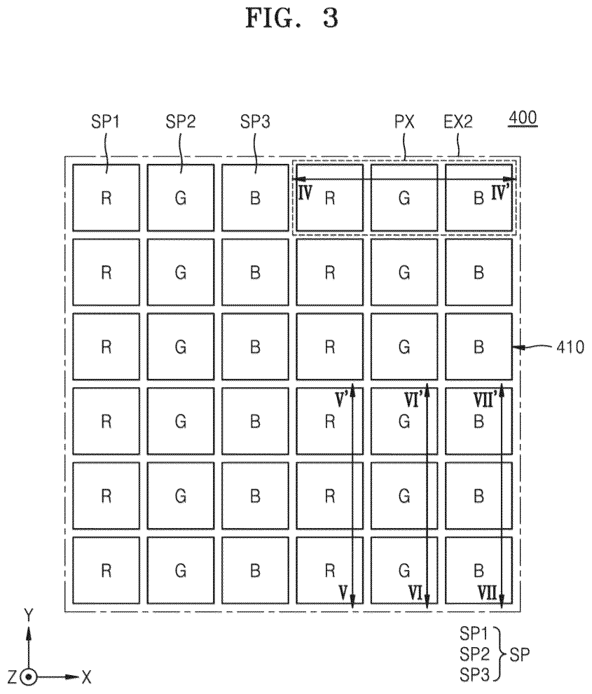

FIG. 1 is a schematic perspective view illustrating a display device according to one or more embodiments. FIG. 2 is a plan view illustrating a pixel region and a conductive layer according to one or more embodiments, and FIG. 3 is an enlarged plan view of a portion indicated by “EX2” of FIG. 1.

Referring to FIGS. 1 to 3, a display device 400 may include a pixel array 410 and a circuit substrate 420 that overlap each other in a vertical direction (the Z direction). The pixel array 410 may include a plurality of pixels PX arranged in a pixel region PXR on the circuit substrate 420. The display device 400 may further include a frame 402 surrounding the pixel array 410 and the circuit substrate 420.

Herein, a direction parallel to a main surface of the circuit substrate 420 may be defined as a horizontal direction (the X direction and/or Y direction), and a direction perpendicular to the horizontal direction (the X direction and/or Y direction) may be defined as a vertical direction (the Z direction).

The circuit substrate 420 may include a plurality of drive circuits. The circuit substrate 420 may be a drive circuit substrate including a plurality of transistors. For example, the circuit substrate 420 may include an application-specific integrated circuit (ASIC) including a plurality of drive circuits. For example, the circuit substrate 420 may include a flexible substrate. In this case, the display device 400 may be implemented as a variable or curved display device.

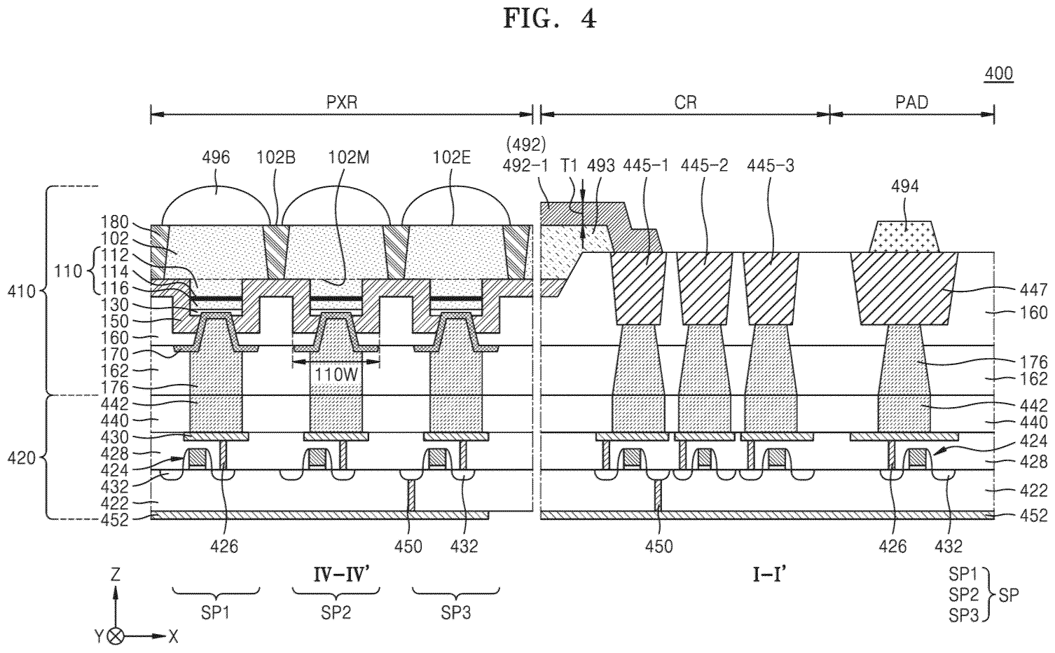

The pixel array 410 may include the pixel region PXR in which a plurality of pixels PX are arranged, a plurality of connection pad regions PAD in which connection pad electrodes 494 (see FIG. 4) are arranged, a connection region CR (see FIG. 4) for interconnecting the plurality of pixels PX and the connection pad electrodes 494, and an edge region ISO.

The plurality of pixels PX may include a plurality of first sub-pixels SP1, a plurality of second sub-pixels SP2, and a plurality of third sub-pixels SP3 configured to emit light having a certain wavelength, for example, light of a certain color. The plurality of first sub-pixels SP1, the plurality of second sub-pixels SP2, and the plurality of third sub-pixels SP3 may each include a light-emitting element.

The light-emitting element may include a light-emitting structure. The light-emitting structure may include a micro light-emitting diode (LED). In one or more embodiments, the light-emitting structure may include a micro LED that emits light of any one color selected from red, green, and blue. The term “micro LED” that is used herein means an LED having a width of about 100 μm or less in a horizontal direction (the X direction and/or Y direction). For example, a width of a semiconductor light-emitting structure 110 (see FIGS. 4 to 10) in the horizontal direction (the X direction and/or Y direction) may be about 100 μm or less, about 50 μm or less, about 20 μm or less, about 10 μm or less, about 6 μm or less, about 5 μm or less, about 4 μm or less, or about 2 μm or less but is not limited thereto.

The light-emitting structure may be configured to emit light having a wavelength λ selected within a range of about 400 nm to about 700 nm.

In one or more embodiments, the light-emitting structure may be configured to emit light having a first wavelength λ1 selected within a range of about 580 nm to about 700 nm. The light having the first wavelength λ1 may be red light. Herein, a wavelength range of red light means a wavelength range of about 580 nm or more and a wavelength range less than about 700 nm, for example, a wavelength range of about 610 nm to about 650 nm, or a wavelength range of about 620 nm to about 640 nm, and may have a peak of at least one light emission spectrum in the wavelength range of the red light.

In another embodiment, the light-emitting structure may be configured to emit light having a second wavelength λ2 selected within a range of about 490 nm to about 580 nm. The light having the second wavelength λ2 may be green light. Herein, a wavelength range of green light means a wavelength range of about 490 nm or more to a wavelength range less than about 580 nm, for example, a wavelength range of about 510 nm to about 550 nm, or a wavelength range of about 520 nm to about 540 nm, and may have a peak of at least one light emission spectrum in the wavelength range of the green light.

In another embodiment, the light-emitting structure may be configured to emit light having a third wavelength λ3 selected within a range of about 400 nm to about 490 nm. The light having the third wavelength λ3 may be blue light. Herein, a wavelength range of blue light means a wavelength range of about 400 nm or more to a wavelength range less than 490 nm, for example, a wavelength range of about 440 nm to about 480 nm, or a wavelength range of about 450 nm to about 470 nm, and may have a peak of at least one light emission spectrum in the wavelength range of the blue light.

The light-emitting element and the light-emitting structure are described in more detail with reference to FIGS. 4 to 7.

The first, second, and third sub-pixels SP1, SP2, and SP3 may be configured to respectively emit red (R) light, green (G) light, and blue (B) light. In one or more embodiments, the plurality of pixels PX may each include the first, second, and third sub-pixels SP1, SP2, and SP3 arranged in a stripe pattern. That is, the plurality of pixels PX may each include the first, second, and third sub-pixels SP1, SP2, and SP3 arranged sequentially. FIG. 3 illustrates, for example, the plurality of pixels PX including the first, second, and third sub-pixels SP1, SP2, and SP3 arranged in a stripe pattern.

In another embodiment, the plurality of pixels PX may include the first, second, and third sub-pixels SP1, SP2, and SP3 arranged in a Bayer pattern. That is, the plurality of pixels PX may each include the first and third sub-pixels SP1 and SP3 arranged in a first diagonal direction and two second sub-pixels SP2 arranged in a second diagonal direction intersecting the first diagonal direction.

In another embodiment, some of the plurality of pixels PX may be configured to emit light of a color, for example, yellow light, other than red (R), green (G), and blue (B). Although FIG. 1 illustrates that the plurality of pixels PX of the pixel array 410 are arranged in a 15′15 matrix in a column direction and a row direction, the plurality of pixels PX are not limited thereto. The pixel array 410 may include a certain number of pixels PX in the column direction and the row direction, for example, a plurality of pixels PX arranged in a 1,024′768 array.

The plurality of connection pad regions PAD may be arranged along an edge of the display device 400 at least on one side of the pixel region PXR. The plurality of connection pad regions PAD may be electrically connected to the plurality of pixels PX and the drive circuits of the circuit substrate 420. The display device 400 may be electrically connected to an external device through the plurality of connection pad regions PAD. The number of connection pad regions PAD included in the display device 400 may be changed. In some embodiments, the number of connection pad regions PAD included in the display device 400 may be determined according to the number of pixels PX included in the pixel array 410, a driving method of the drive circuits included in the circuit substrate 420, and so on.

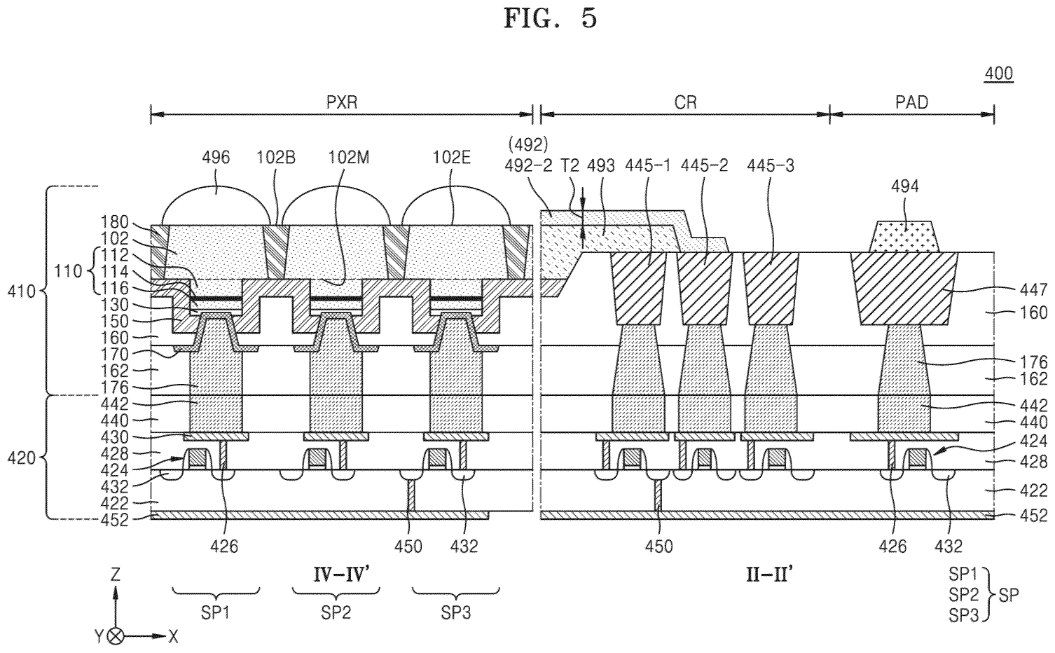

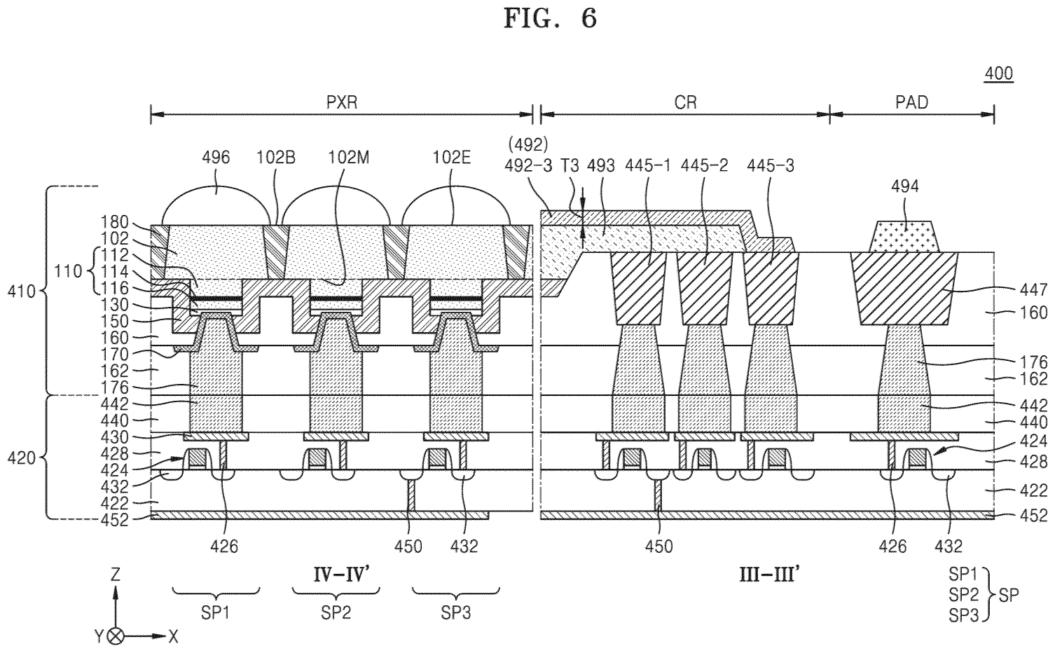

The connection region CR may be between the pixel region PXR and the plurality of connection pad regions PAD. A wiring structure electrically connected to the plurality of pixels PX, for example, a part of a first electrode 492 illustrated in FIG. 4 and conductive layers 445 may be arranged in the connection region CR. a first wire 492-1 (see FIG. 4), a second wire 492-2 (see FIG. 5), and a third wire 492-3 (see FIG. 6) may be collectively referred to as a wire, and the wire may also be referred to as the first electrode 492.

The edge region ISO of the display device 400 may be a region along edges of the pixel array 410. The semiconductor light-emitting structure 110 may not be arranged in the edge region ISO.

The frame 402 of the display device 400 may be arranged around the pixel array 410 to serve as a guide for defining an arrangement space of the pixel array 410. The frame 402 may include polymer, ceramic, semiconductor, metal, or a combination thereof.

Also, the display device 400 may further include the conductive layers 445 that surround the pixel region PXR in a plan view. The conductive layers 445 may be arranged in the connection region CR. The conductive layers 445 may be electrically connected to sub-pixels SP including the first, second, and third sub-pixels SP1, SP2, and SP3. An electrical connection between the conductive layers 445 and the sub-pixels SP is described in more detail with reference to FIGS. 4 to 10.

The conductive layers 445 may be two or more layers. Although FIG. 2 illustrates three conductive layers 445 including first, second, and third conductive layers 445-1, 445-2, and 445-3 as an example, the three conductive layers 445 may be provided in two or four or more. In a planar view, the first, second, and third conductive layers 445-1, 445-2, and 445-3 may each have a square ring shape. The square ring shape may include a square shape hollow inside of square. The first, second, and third conductive layers 445-1, 445-2, and 445-3 may be separated from each other in a horizontal direction (the X direction and/or Y direction).

The number of electrically separated wires may be determined based on the number of electrically separated conductive layers 445. For example, the number of electrically separated conductive layers 445 may be equal to the number of electrically separated wires.

The conductive layers 445 may each include a conductive material, for example, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), or a combination thereof.

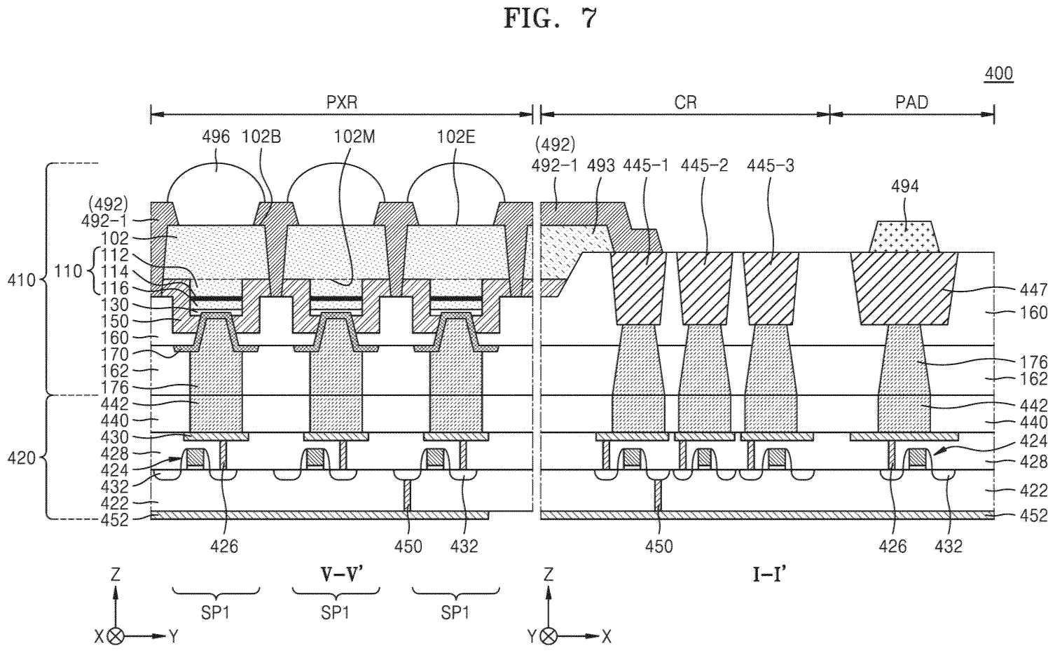

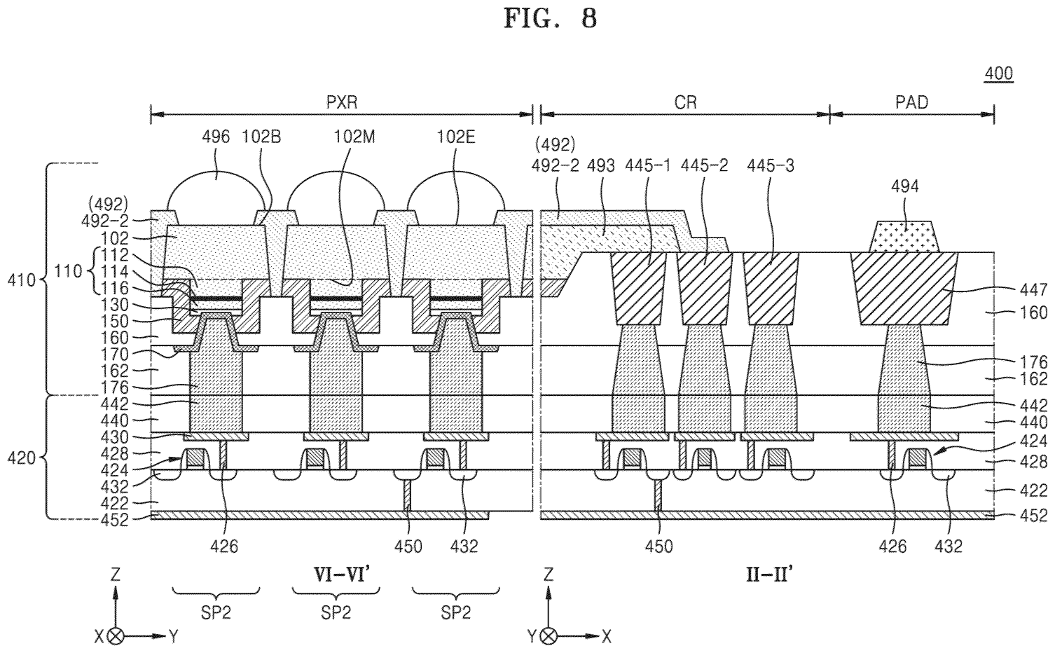

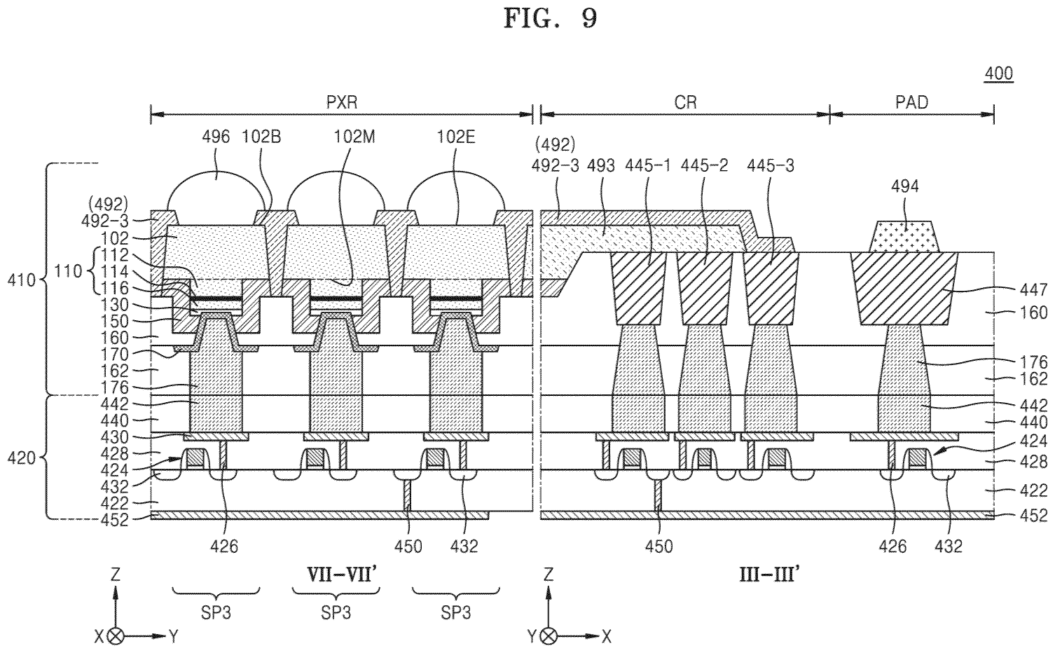

FIGS. 4 to 9 are views illustrating a display device according to one or more embodiments, and FIG. 4 schematically illustrates components taken along line I-I′ of FIG. 1 and components taken along line IV-IV′ of FIG. 3. FIG. 5 schematically illustrates components taken along line II-II′ of FIG. 1 and components taken along line IV-IV′ of FIG. 3. FIG. 6 schematically illustrates components taken along line III-III′ of FIG. 1 and components taken along line IV-IV′ of FIG. 3. FIG. 7 schematically illustrates components taken along line I-I′ of FIG. 1 and components taken along line V-V′ of FIG. 3. FIG. 8 schematically illustrates components taken along line II-II′ of FIG. 1 and components taken along line VI-VI′ of FIG. 3. FIG. 9 schematically illustrates components taken along line III-III′ of FIG. 1 and components taken along line VII-VII′ of FIG. 3. Descriptions are made with reference to FIGS. 1 to 3 together.

Referring to FIGS. 4 to 9, the circuit substrate 420 may include a semiconductor substrate 422, a drive circuit including a plurality of driving elements 424 formed on the semiconductor substrate 422 and including a plurality of transistors, a plurality of interconnection portions 426 electrically connected to the plurality of driving elements 424, and a plurality of wiring lines 430 connected to the plurality of interconnection portions 426. The plurality of driving elements 424, the plurality of interconnection portions 426, and the plurality of wiring lines 430 included in the drive circuit may be covered with an insulating layer 428.

The circuit substrate 420 may further include a first bonding insulating layer 440 on the insulating layer 428, and a plurality of first bonding electrodes 442 passing through the first bonding insulating layer 440 and connected to the plurality of wiring lines 430.

The semiconductor substrate 422 may include a plurality of impurity regions 432 constituting source/drain regions of a plurality of transistors included in the plurality of driving elements 424. The semiconductor substrate 422 may include a semiconductor, such as silicon (Si) or germanium (Ge), or a compound semiconductor, such as SiGe, SiC, GaAs, InAs, or InP. The semiconductor substrate 422 may further include a plurality of through-electrodes 450, such as through silicon vias (TSVs), connected to the drive circuit, and a plurality of substrate wiring lines 452 connected to the plurality of through-electrodes 450.

The drive circuit may control driving of the plurality of pixels PX or the first, second, and third sub-pixels SP1, SP2, and SP3. Some of the plurality of impurity regions 432 may be electrically connected to at least one selected from among the plurality of first, second, and third sub-pixels SP1, SP2, and SP3 through the interconnection portion 426, the wiring line 430, and the first bonding electrode 442. In one or more embodiments, some of the plurality of impurity regions 432 may be connected to one of the plurality of substrate wiring lines 452 through the through-electrode 450.

Upper surfaces of the plurality of first bonding electrodes 442 and an upper surface of the first bonding insulating layer 440 may constitute an upper surface of the circuit substrate 420. The plurality of first bonding electrodes 442 included in the circuit substrate 420 may be respectively bonded to the plurality of second bonding electrodes 176 included in the pixel array 410 to provide electrical connection paths. In some embodiments, the plurality of first bonding electrodes 442 and the plurality of second bonding electrodes 176 may each include a copper (Cu) layer. The plurality of first bonding electrodes 442 and the plurality of second bonding electrodes 176 may each further include a barrier metal layer surrounding the copper (Cu) layer. The barrier metal layer may include Ta, TaN, or a combination thereof.

The first bonding insulating layer 440 included in the circuit substrate 420 may be bonded to a second bonding insulating layer 162 included in the pixel array 410. The first bonding insulating layer 440 and the second bonding insulating layer 162 may each include SiO, SiN, SiCN, SiOC, SiON, SiOCN, or a combination thereof.

The first, second, and third sub-pixels SP1, SP2, and SP3 included in the pixel array 410 may each include the semiconductor light-emitting structure 110. More specifically, the pixel array 410 may include a first conductive base semiconductor layer 102 having a main surface 102M and a back surface 102B that are opposite surfaces to each other, and a plurality of semiconductor light-emitting structures 110 arranged on the main surface 102M of the first conductive base semiconductor layer 102. The plurality of semiconductor light-emitting structures 110 may be separated from each other in a horizontal direction (the X direction and/or Y direction). The plurality of semiconductor light-emitting structures 110 may each include a first conductive semiconductor layer 112, an active layer 114, and a second conductive semiconductor layer 116 that are sequentially stacked in a vertical direction (the Z direction).

The first conductive base semiconductor layer 102, the first conductive semiconductor layer 112, the active layer 114, and the second conductive semiconductor layer 116 may each include an epitaxial nitride semiconductor layer. The first conductive base semiconductor layer 102 and the first conductive semiconductor layer 112 include nitride semiconductor layers doped with a dopant of the same conductive type, for example, an n-type dopant, and an average doping concentration of the first conductive base semiconductor layer 102 may be greater than an average doping concentration of the first conductive semiconductor layer 112. The first conductive semiconductor layer 112 and the second conductive semiconductor layer 116 may each include a single layer, or may include a multilayer including a plurality of layers having different doping concentrations of dopants, different compositions of components, and so on. The first conductive base semiconductor layer 102 may be separated from the active layer 114 in a vertical direction (the Z direction) with the first conductive semiconductor layer 112 therebetween.

In the semiconductor light-emitting structure 110, the first conductive semiconductor layer 112 may have a structure integrally connected to the first conductive base semiconductor layer 102. In one or more embodiments, the first conductive base semiconductor layer 102 and the first conductive semiconductor layer 112 may include the same material. In one or more embodiments, the first conductive base semiconductor layer 102 may include n-type gallium nitride (n-GaN). The first conductive semiconductor layer 112 may include an n-type superlattice structure layer. For example, the first conductive semiconductor layer 112 may include an InGaN/GaN superlattice structure layer. In this case, the first conductive semiconductor layer 112 may have a superlattice structure in which InGaN layers and GaN layers are alternately stacked one by one. In the first conductive semiconductor layer 112, the superlattice structure may include a pair structure of the InGaN layer and the GaN layer in about 10 to about 50 cycles, for example, about 15 to about 20 cycles, but the superlattice structure is not limited thereto.

In another embodiment, the first conductive semiconductor layer 112 may include a nitride semiconductor layer having a composition of InₓAl_{y}Ga_{1-x-y}N (0≤x<1, 0≤y<1, and 0≤x+y<1). In another embodiment, the first conductive semiconductor layer 112 may include n-type gallium nitride (n-GaN) doped with silicon (Si), germanium (Ge), or carbon (C). In another embodiment, the first conductive semiconductor layer 112 may include a semiconductor layer formed of aluminum indium gallium phosphide (AlInGaP) or aluminum indium gallium arsenide (AlInGaAs).

In the semiconductor light-emitting structure 110, the active layer 114 may be configured to emit light having a predetermined energy by recombination of electrons and holes. The active layer 114 may have a single quantum well or multi-quantum well structure in which a quantum barrier layer and a quantum well layer are alternately arranged. In one or more embodiments, the active layer 114 may have a single or multi-quantum well structure in which a pair structure including one quantum barrier layer and one quantum well layer is included in one to 15 cycles.

In one or more embodiments, the active layer 114 may include a quantum barrier layer and a quantum well layer, each being formed of a compound semiconductor of a III-V group element. For example, the active layer 114 may have a pair structure including materials selected from InGaN/GaN, InGaN/InGaN, InGaN/AlGaN, and InGaN/InAlGaN but is not limited thereto.

In one or more embodiments, the quantum well layer and the quantum barrier layer may include InₓAl_{y}Ga_{1-x-y}N (0≤x≤1, 0≤y≤1, 0≤x+y≤1) layers having different compositions. For example, the quantum well layer may include an undoped InₓGa₁₋ₓN (0<x<1) layer, and the quantum barrier layer may include an undoped GaN layer or a GaN layer doped with silicon (Si).

In one or more embodiments, when the quantum well layer included in the active layer 114 is an InₓGa₁₋ₓN (0<x<1) layer, band gap energy in the active layer 114 may be adjusted according to a content ratio of indium (In) in the quantum well layer, and accordingly, a light emission wavelength band may be adjusted. When the quantum well layer included in the active layer 114 is the InₓGa₁₋ₓN (0<x<1) layer, an x value, which means the content ratio of indium (In) in the quantum well layer, may be selected within a range of about 0.15 to about 0.35. For example, when the semiconductor light-emitting structure 110 is configured to emit red light, the x value in the InₓGa₁₋ₓN (0<x<1) layer constituting the quantum well layer included in the active layer 114 may be selected within a range of about 0.3 to about 0.35, when the semiconductor light-emitting structure 110 is configured to emit green light, the x value in the InₓGa₁₋ₓN (0<x<1) layer constituting the quantum well layer included in the active layer 114 may be selected within a range of about 0.25 to about 0.3, and when the semiconductor light-emitting structure 110 is configured to emit blue light, the x value in the InₓGa₁₋ₓN (0<x<1) layer constituting the quantum well layer included in the active layer 114 may be selected within a range of about 0.15 to about 0.2, but the embodiment is not limited thereto.

In one or more embodiments, the active layer 114 may include a multi-quantum well layer having a pair structure in which one quantum barrier layer and one quantum well layer are included in 8 to 12 cycles, and the multi-quantum well layer may have a surface in contact with the first conductive semiconductor layer 112 and a surface in contact with the second conductive semiconductor layer 116.

the second conductive semiconductor layer 116 of the semiconductor light-emitting structure 110 may include a nitride semiconductor layer doped with a p-type dopant. In one or more embodiments, the second conductive semiconductor layer 116 may include a nitride semiconductor layer having a composition of InₓAl_{y}Ga_{1-x-y}N (0≤x<1, 0≤y<1, and 0≤x+y<1). For example, the second conductive semiconductor layer 116 may include p-type gallium nitride (p-GaN) doped with magnesium (Mg) or zinc (Zn). However, the disclosure is not limited to the examples described above. In another embodiment, the second conductive semiconductor layer 116 may include a semiconductor layer formed of aluminum indium gallium phosphide (AlInGaP) or aluminum indium gallium arsenide (AlInGaAs).

The pixel array 410 of the display device 400 may further include a plurality of transparent electrode layers 130, a reflective structure 150, and a reflective electrode layer 170 passing through the reflective structure 150 to be in contact with the transparent electrode layer 130.

The transparent electrode layer 130 may be in contact with the second conductive semiconductor layer 116 and may be separated, in a vertical direction (the Z direction), from the active layer 114 with the second conductive semiconductor layer 116 therebetween. The reflective electrode layer 170 may be in contact with the transparent electrode layer 130 and may be separated, in the vertical direction (Z direction), from the second conductive semiconductor layer 116 with the transparent electrode layer 130 therebetween. Herein, the transparent electrode layer 130 may be referred to as an electrode layer, and the reflective electrode layer 170 may be referred to as an electrode layer or a second electrode.

As illustrated in FIG. 4, the second conductive semiconductor layer 116 may have a surface in contact with the active layer 114 and a surface in contact with the transparent electrode layer 130, and the surface in contact with the active layer 114 may be opposite, in the vertical direction (the Z direction), to the surface in contact with the transparent electrode layer 130 of the second conductive semiconductor layer 116.

The semiconductor light-emitting structure 110 may have a pillar shape having a central axis extending in the vertical direction (the Z direction). The semiconductor light-emitting structure 110 may have a width 110W less than about 100 μm in the horizontal direction (the X direction and/or Y direction). In some embodiments, the width 110W of the semiconductor light-emitting structure 110 may be between about 100 nm and about 10 μm or may be between about 500 nm and about 1500 nm. The transparent electrode layer 130 may have a width that is equal or similar to the width 110W of the semiconductor light-emitting structure 110 in the horizontal direction (the X direction and/or Y direction).

The transparent electrode layer 130 may include a transparent conductive material. In some embodiments, the transparent electrode layer 130 may include indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In4Sn3O12, zinc magnesium oxide (Zn(1−x)MgxO; 0≤x≤1), or a combination thereof.

For example, the reflective electrode layer 170 may include silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), titanium (Ti), titanium nitride (TiN), tantalum (Ta), tantalum nitride (TaN), tungsten (W), or a combination thereof but is not limited thereto.

In a plan view, the semiconductor light-emitting structure 110 may have various planar shapes. For example, the semiconductor light-emitting structure 110 may have a planar shape of a circle, an ellipse, or a polygon. The polygon may be a square, a hexagon, or an octagon but is not limited thereto. In a planar view, the planar shape of the transparent electrode layer 130 may be the same as or similar to the planar shape of the semiconductor light-emitting structure 110. The semiconductor light-emitting structure 110 and the transparent electrode layer 130 may form a single pillar shape.

A side wall of each of the first conductive semiconductor layer 112, the active layer 114, and the second conductive semiconductor layer 116 included in the semiconductor light-emitting structure 110, and a side wall of the transparent electrode layer 130 may be covered with the reflective structure 150. In a plan view, the semiconductor light-emitting structure 110 and the transparent electrode layer 130 may be surrounded by the reflective structure 150. The reflective structure 150 may include a distributed Bragg reflector (DBR). For example, the reflective structure 150 may include different materials selected from SiO₂, SiON, TiO₂, Si₃N₄, Al₂O₃, TiN, AlN, ZrO₂, TiAlN, TiSiN, HfO, NbO₂, TaO₂, and MgF₂.

The reflective structure 150 may adjust light distribution by reflecting the light that progresses from the inside of the semiconductor light-emitting structure 110 to a side wall. Because the reflective structure 150 includes a DBR, the reflective structure 150 may serve as a band pass filter (BPF) that prevents light having a certain wavelength from transmitting therethrough and may effectively adjust the light distribution because there is a difference in transmittance according to an incident angle. Also, the reflective structure 150 may relatively and greatly increase intensity of the light emitted from a certain region by using a difference in transmittance according to an incident angle of the light emitted from the semiconductor light-emitting structure 110.

The light-emitting element 100 may include the insulating layer 160 that covers the reflective structure 150. In some embodiments, the insulating layer 160 may include silicon oxide. For example, the insulating layer 160 may include tetraethyl ortho silicate (TEOS), undoped silicate glass (USG), phosphosilicate glass (PSG), borosilicate glass (BSG), borophosphosilicate glass (BPSG), fluoride silicate glass (FSG), spin on glass (SOG), polysilazane, or a combination thereof.

The reflective electrode layer 170 may partially cover the insulating layer 160 and may pass through the reflective structure 150 in a vertical direction (the Z direction) to be in contact with the transparent electrode layer 130. The reflective electrode layer 170 may include portions in contact with the insulating layer 160 and portions in contact with the reflective structure 150.

The pixel array 410 may further include the first electrode 492 that passes through the first conductive base semiconductor layer 102 in a vertical direction (the Z direction). The first electrode 492 may include a metal layer. The first electrode 492 may be between adjacent identical sub-pixels SP. In another embodiment, the first electrode 492 may be between adjacent different sub-pixels SP. In this case, the different sub-pixels SP may be electrically connected to each other. Therefore, voltages applied to cathodes of the different sub-pixels SP may be equal to each other. Also, magnitudes of the voltages applied to the different sub-pixels SP may be equal to each other. Herein, when it is described that voltages are applied to components, those components are configured to receive such voltages.

The first electrode 492 may be formed at a vertical level higher than the back surface 102B of the first conductive base semiconductor layer 102 and may extend into a part of the reflective structure 150 in a vertical direction (the Z direction).

A part of the first electrode 492 may be in contact with a sidewall of the first conductive base semiconductor layer 102. Another part of the first electrode 492 may be in contact with the back surface 102B of the first conductive base semiconductor layer 102 to define a light-emitting surface 102E formed as a part of the back surface 102B of the first conductive base semiconductor layer 102. In some embodiments, the first electrode 492 may include silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), or a combination thereof.

The pixel array 410 may further include a separation layer 180 that passes through the first conductive base semiconductor layer 102 in a vertical direction (the Z direction). The separation layer 180 may electrically separate adjacent different sub-pixels SP from each other. The separation layer 180 may be between adjacent different sub-pixels SP. The separation layer 180 may be formed at the same vertical level as a vertical level of the light-emitting surface 102E of the first conductive base semiconductor layer 102 and may extend in a vertical direction (the Z direction) to be in contact with the reflective structure 150. Therefore, an upper surface of the first electrode 492 may be at a higher vertical level than an upper surface of the separation layer 180. In one or more embodiments, the separation layer 180 may extend into at least a part of the reflective structure 150. The separation layer 180 may be in contact with a side wall of the first conductive base semiconductor layer 102. The separation layer 180 may include an insulating layer. For example, the separation layer 180 may include SiO, SiN, SiCN, SiOC, SiON, SiOCN, or a combination thereof.

A plurality of microlenses 496 may be arranged on the light-emitting surface 102E defined by the first electrode 492, in the back surface 102B of the first conductive base semiconductor layer 102. The plurality of microlenses 496 may each be in contact with a portion covering the back surface 102B of the first electrode 492 and/or the back surface 102B. The plurality of microlenses 496 may respectively overlap a plurality of semiconductor light-emitting structures 110 in a vertical direction (the Z direction).

Each of the plurality of microlenses 496 may be configured to extract the light emitted from each of the semiconductor light-emitting structures 110. The plurality of microlens 496 may each be separated from the first conductive semiconductor layer 112 in a vertical direction (the Z direction) with the first conductive base semiconductor layer 102 therebetween. The first conductive base semiconductor layer 102 may be in contact with the main surface 102M in contact with the first conductive type semiconductor layer 112 and may be in contact with the light-emitting surface 102E formed as a part of the back surface 102B which is a surface opposite to the main surface 102M. The plurality of microlens 496 may each overlap the semiconductor light-emitting structure 110 in a vertical direction (the Z direction). The plurality of microlens 496 may improve the light extraction efficiency of the light-emitting element (100).

In one or more embodiments, the plurality of microlens 496 may each include a spherical microlens or an aspherical microlens. In one or more embodiments, the plurality of microlens 496 may each include a graded-refractive index layer having a multilayer structure in which a refractive index gradually decreases in a light propagation direction. The graded-refractive index layer may be formed by using an oblique deposition method, a sputtering method, an evaporation method, or so on. The graded-refractive index layer may be configured to gradually decrease the refractive index in a direction of a light-emitting surface. For example, the plurality of microlens 496 may each include TiO₂, SiC, GaN, GaP, SiN, SiON, ZrO₂, ITO, AlN, Al₂O₃, MgO, SiO₂, CaF₂, MgF₂, or a combination thereof but is not limited thereto.

In the pixel array 410 of the display device 400, the plurality of second bonding electrodes 176 may be respectively connected to a plurality of reflective electrode layers 170, and the second bonding insulating layer 162 surrounding the plurality of second bonding electrodes 176 may be in contact with a part of the reflective electrode layer 170 and may be in contact with the insulating layer 160 covering the reflective structure 150.

The display device 400 may further include the conductive layer 445 and an inner pad electrode 447. In the pixel array 410, the insulating layer 160 covering the reflective electrode layer 170 may extend to the connection region CR and the connection pad region PAD to cover the conductive layer 445 and the inner pad electrode 447.

The first electrode 492 may extend from the pixel region PXR to the connection region CR and may be in physical contact with the first conductive base semiconductor layer 102 and the conductive layer 445 in the connection region CR. The first electrode 492 may be configured to be electrically connectable to the first conductive base semiconductor layer 102 and the conductive layer 445. The first electrode 492 electrically connects the plurality of sub-pixels SP to each other and may be referred to as a wire herein. The connection pad electrode 494 may be on the inner pad electrode 447 in the connection pad region PAD.

For example, the first electrode 492 electrically connected to the first conductive layer 445-1 may be referred to as the first wire 492-1, the first electrode 492 electrically connected to the second conductive layer 445-2 may be referred to as the second wiring 492-2, and the first electrode 492 electrically connected to the third conductive layer 445-3 may be referred to as the third wire 492-3. The first wire 492-1 may be electrically connected to the first sub-pixel SP1, the second wire 492-2 may be electrically connected to the second sub-pixel SP2, and the third wire 492-3 may be electrically connected to the third sub-pixel SP3. In one or more embodiments, the first, second, and third wires 492-1, 492-2, and 492-3 may be respectively and electrically separated from each other. Different voltages may be respectively applied to the first, second d, and third wires 492-1, 492-2, and 492-3. In one or more embodiments, voltages respectively applied to the first, second, and third sub-pixels SP1, SP2, and SP3 may be different from each other. A voltage applied to the sub-pixel SP may be calculated by a difference between a voltages applied to an anode of the sub-pixel SP and a voltage applied to a cathode of the sub-pixel SP. The anode of the sub-pixel SP may be the reflective electrode layer 170, and the cathode of the sub-pixel SP may be the first electrode 492.

The display device 400 may further include a wiring insulation layer 493 to independently control the first, second, and third electrodes 492-1, 492-2, and 493-3. The wiring insulation layer 493 may be provided between the wire 492 and the insulating layer 160. The wiring insulation layer 493 may include an insulating material. For example, the wiring insulation layer 493 may include SiO, SiN, SiCN, SiOC, SiON, SiOCN, or a combination thereof.

In one or more embodiments, the wiring insulation layer 493 may cause the first wire 492-1 to be electrically connected to the first conductive layer 445-1 and cause the first wire 492-1 to be electrically separated from the second conductive layer 445-2 and the third conductive layer (445-3). Also, the wiring insulation layer 493 may cause the second wire 492-2 to be electrically connected to the second conductive layer 445-2 and cause the second wire 492-2 to be electrically separated from the first conductive layer 445-1 and the third conductive layer 445-3. In addition, the wiring insulation layer 493 may cause the third wire 492-3 to be electrically connected to the third conductive layer 445-3 and cause the third wire 492-3 to be electrically separated from the first conductive layer 445-1 and the second conductive layer 445-2.

In one or more embodiments, at least two of the first, second, and third wires 492-1, 492-2, and 492-3 may have different cross-sectional areas. For example, a cross-sectional area of the first wire 492-1 may be greater than a cross-sectional area of each of the second wire 492-2 and the third wire 492-3. A cross-sectional area of a wire may be selected based on intensity of a current flowing through the wire. In one or more embodiments, as the intensity of a current flowing through a wire increases, a cross-sectional area of the wire may increase. When the cross-sectional area of the wire increases, resistance of the wire may decrease. A cross-sectional area of a wire may be proportional to a width of the wire in a horizontal direction (the X direction and/or Y direction) and a thickness of the wire in a vertical direction (the Z direction). For example, a first thickness T1, which is a thickness of the first wire 492-1 in the vertical direction (the Z direction), may be greater than a second thickness T2 and a third thickness T3, which are respectively a thickness of the second wire 492-2 in the vertical direction (the Z direction) and a thickness of the third wire 492-3 in the vertical direction (the Z direction). In another embodiment, the first, second, and third thicknesses T1, T2, and T3 may be equal to each other.

The plurality of second bonding electrodes 176 may be respectively connected to the conductive layers 445. As described above, in a plan view, the conductive layers 445 may each have a ring shape or a square ring shape surrounding the pixel region PXR. A plurality of conductive layers 445 are provided, and the plurality of conductive layers 445 may be separated from each other in a horizontal direction (the X direction and/or Y direction).

In the connection pad region PAD, the connection pad electrode 494 may be arranged on the inner pad electrode 447. The inner pad electrode 447 may be in contact with the connection pad electrode 494. The inner pad electrode 447 may be between the connection pad electrode 494 and the second bonding electrode 176 to connect the connection pad electrode 494 to the second bonding electrode 176. The inner pad electrode 447 may include a conductive material, for example, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), or a combination thereof.

The connection pad electrode 494 may be connected to an external device, or an external circuit (an external integrated circuit (IC)) that may apply an electrical signal to the circuit substrate 420, by wire bonding or anisotropic conductive film (ACF) bonding. The connection pad electrode 494 may electrically connect drive circuits of the circuit substrate 420 to an external device. The connection pad electrode 494 may include a metal, for example, gold (Au), silver (Ag), or nickel (Ni).

Among the plurality of second bonding electrodes, the second bonding electrode 176 arranged in the pixel region PXR may be connected to the reflective electrode layer 170, the second bonding electrode 176 arranged in the connection region CR may be connected to the conductive layer 445, and the second bonding electrode 176 arranged in the connection pad region PAD may be connected to the inner pad electrode 447. The first electrode 492 may be connected to the second bonding electrode 176 through the conductive layer 445.

A surface of the second bonding insulating layer 162 facing the circuit substrate 420 and surfaces of the plurality of second bonding electrodes 176 facing the circuit substrate 420 may extend in one plane. The second bonding insulating layer 162 may be bonded to the first bonding insulating layer 440 through dielectric-dielectric bonding. The circuit substrate 420 and the pixel array 410 may be bonded to each other by bonding of a plurality of first bonding electrodes 442 and the plurality of second bonding electrodes 176 and bonding of the first bonding insulating layer 440 and the second bonding insulating layer 162.

In some embodiments, the bonding of the plurality of first bonding electrodes 442 and the plurality of second bonding electrodes 176 may be, for example, copper (Cu)-copper (Cu) bonding, and the bonding of the first bonding insulating layer 440 and the second bonding insulating layer 162 may be, for example, dielectric-dielectric bonding, such as SiCN—SiCN bonding. The circuit substrate 420 and the pixel array 410 may be bonded to each other by hybrid bonding including the copper (Cu)-copper (Cu) bonding and the dielectric-dielectric bonding, and may be bonded to each other without a separate adhesive layer.

The display device 400 according to the disclosure may include a plurality of wires connecting the plurality of semiconductor light-emitting structures 110 to the plurality of conductive layers 445, and the plurality of wires may be electrically separated from each other to independently control driving voltages of the plurality of semiconductor light-emitting structures 110. Therefore, the display device 400 according to the disclosure may reduce heat generation of the display device 400, extend a lifespan of the display device 400, and increase efficiency of the display device 400.

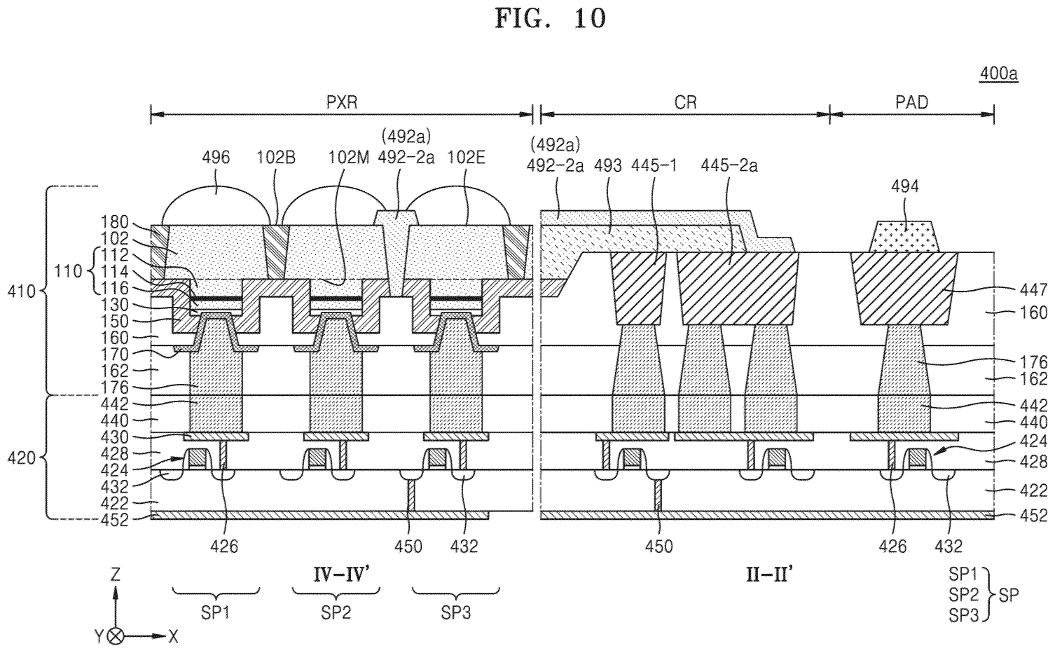

FIG. 10 is a view illustrating a display device according to another embodiment and schematically illustrates components taken along line II-II′ of FIG. 1 and components taken along line IV-IV′ of FIG. 3.

Referring to FIG. 10, a display device 400a may include a first conductive layer 445-1 and a second conductive layer 445-2a, and the first and second conductive layers 445-1 and 445-2a may be collectively referred to as a conductive layer 445a. The first conductive layer 445-1 of FIG. 10 is substantially the same as the first conductive layer 445-1 of the conductive layer 445 of FIGS. 3 to 7, and accordingly, the second conductive layer 445-2a is mainly described herein.

The second conductive layer 445-2a may be electrically connected to a second wire 492-2a. The first conductive layer 445-1 may be electrically separated from the second conductive layer 445-2a. Here, the second wire 492-2a may be electrically connected to each of a second sub-pixel SP2 and a third sub-pixel SP3. In one or more embodiments, the same voltage may be applied to a cathode of each of the second sub-pixel SP2 and the third sub-pixel SP3. Therefore, the same voltage may be applied to the second sub-pixel SP2 and the third sub-pixel SP3. In another embodiment, a difference between a voltage applied to the second sub-pixel SP2 and a voltage applied to the third sub-pixel SP3 may be about 1 V or less. Therefore, the first sub-pixel SP1 electrically connected to a first wire 492-1 may be electrically separated from each of the second sub-pixel SP2 and the third sub-pixel SP3 electrically connected to the second wire 492-2a.

In one or more embodiments, a separation layer 180 may be between the first sub-pixel SP1 and the second sub-pixel SP2 to electrically separate the first sub-pixel SP1 from the second sub-pixel SP2. Also, a first electrode 492a may be between the second sub-pixel SP2 and the third sub-pixel SP3 to electrically connect the second sub-pixel SP2 to the third sub-pixel SP3.

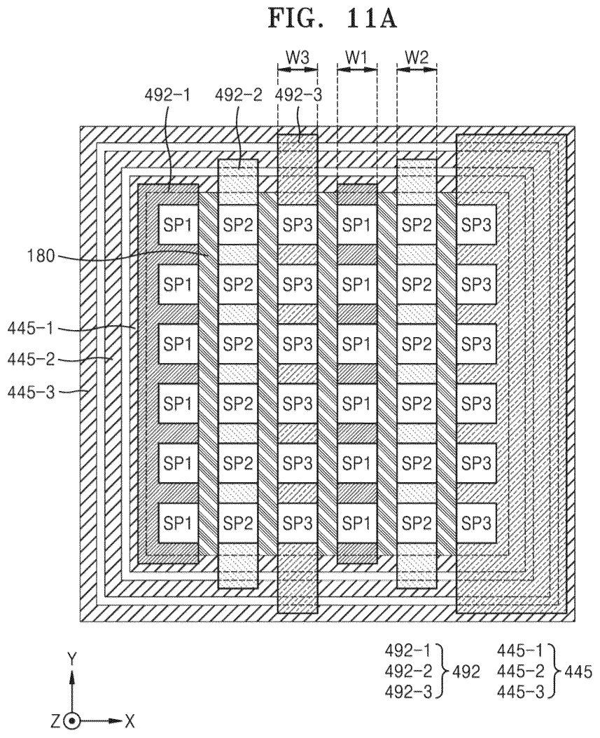

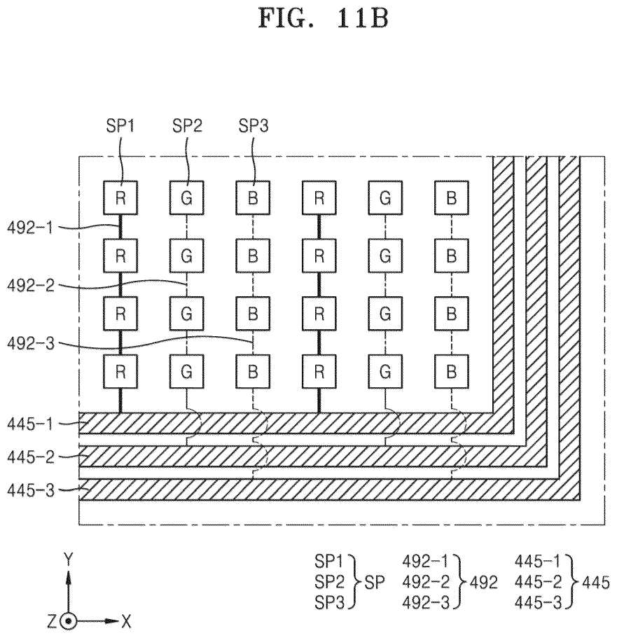

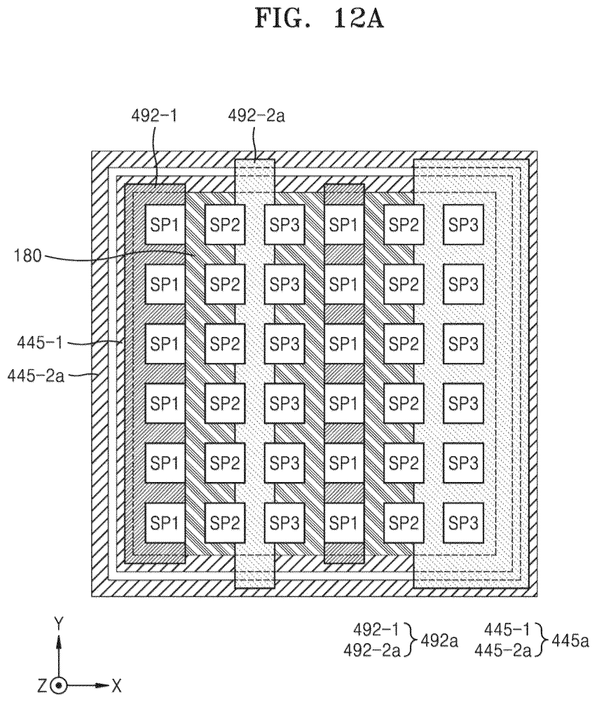

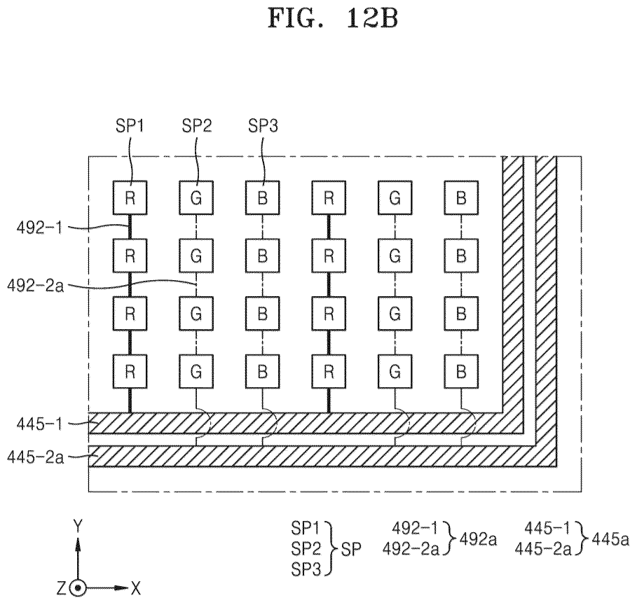

FIG. 11A is a plan view illustrating a display device according to one or more embodiments, and FIG. 11B is a view schematically illustrating a region of the display device of FIG. 11A corresponding to a region A of FIG. 2. FIG. 12A is a plan view illustrating a display device according to one or more embodiments, and FIG. 12B is a view schematically illustrating a region of the display device of FIG. 12A corresponding to the region A of FIG. 2. FIG. 11B is a view schematically illustrating an electrical connection relationship between sub-pixels SP, wires, and conductive layers 445, and FIG. 12B is a view schematically illustrating an electrical connection relationship between sub-pixels SP, wires, and conductive layers 445a. Although FIG. 11A and FIG. 12A illustrate that sub-pixels are arranged in a 6′6 array in a pixel array for the sake of convenience of description, this is only an example, and the number of sub-pixels arranged in the pixel array may be changed.

Referring to FIG. 11A and FIG. 11B, a plurality of first sub-pixels SP1 may be electrically connected to each other by a first wire 492-1 and may be electrically connected to a first conductive layer 445-1. Also, a plurality of second sub-pixels SP2 may be electrically connected to each other by a second wire 492-2 and may be electrically connected to a second conductive layer 445-2. In addition, a plurality of third sub-pixels SP3 may be electrically connected to each other by a third wire 492-3 and may be electrically connected to a third conductive layer 445-3. The first, second, and third wires 492-1, 492-2, and 492-3 may be electrically separated from each other, and the first, second, and third conductive layers 445-1, 445-2, and 445-3 may also be electrically separated from each other. As described above, different voltages may be applied to the first, second, and third conductive layers 445-1, 445-2, and 445-3, and accordingly, different voltages may be applied to the first, second, and third sub-pixels SP1, SP2, and SP3.

In one or more embodiments, at least two of the first, second, and third wires 492-1, 492-2, and 492-3 may have different cross-sectional areas. Although FIGS. 11A and 11B illustrate that the first wire 492-1 has a greater cross-sectional area than each of the second and third wires 492-2 and 492-3, the disclosure is not limited thereto. In another embodiment, the first, second, and third wires 492-1, 492-2, and 492-3 may have the same cross-sectional area.

A wire 492 arranged in a peripheral region may have a greater horizontal width in a horizontal direction (the X direction and/or Y direction) than another wire 492 that is not arranged in the peripheral region. In one or more embodiments, the first wire 492-1 that is not arranged in the peripheral region may have a first width W1 in a first horizontal direction (the X direction), the second wire 492-2 that is not arranged in the peripheral region may have a second width W2 in the first horizontal direction (the X direction), and the third wire 492-3 that is not arranged in the peripheral region may have a third width W3) in the first horizontal direction (the X direction). In one or more embodiments, the first width W1 may be greater than the second width W2 and the third width W3. In another embodiment, the first width W1, the second width W2, and the third width W3 may be equal to each other.

Referring to FIGS. 12A and 12B, a plurality of first sub-pixels SP1 may be electrically connected to each other by a first wire 492-1 and may be electrically connected to a first conductive layer 445-1. Also, a plurality of second sub-pixels SP2 may be electrically connected to each other by a second wire 492-2a and may be electrically connected to a second conductive layer 445-2a, and also, a plurality of third sub-pixels SP3 may be electrically connected to each other by the second wire 492-2a and may be electrically connected to the second conductive layer 445-2a. The first wire 492-1 may be electrically separated from the second wire 492-2a, and the first conductive layer 445-1 may also be electrically separated from the second conductive layer 445-2a. As described above, different voltages may be applied to the first conductive layer 445-1 and the second conductive layer 445-2a, and accordingly, a voltage applied to the first sub-pixel SP1 may be different from voltages applied to the second sub-pixel SP2 and the third sub-pixel SP3.

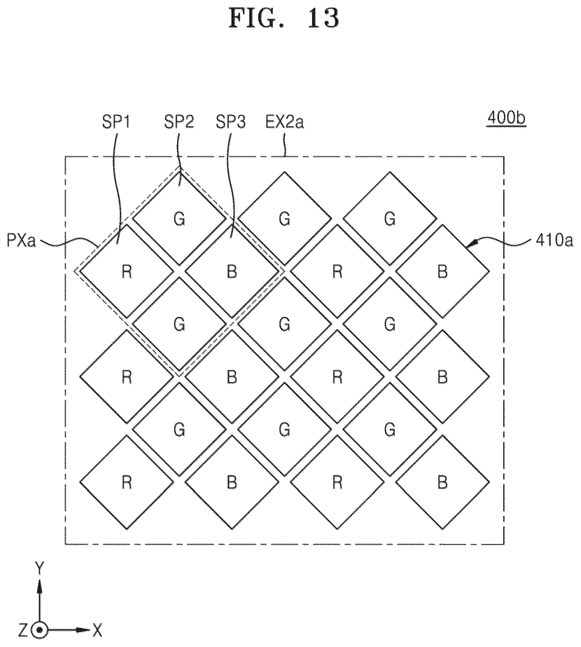

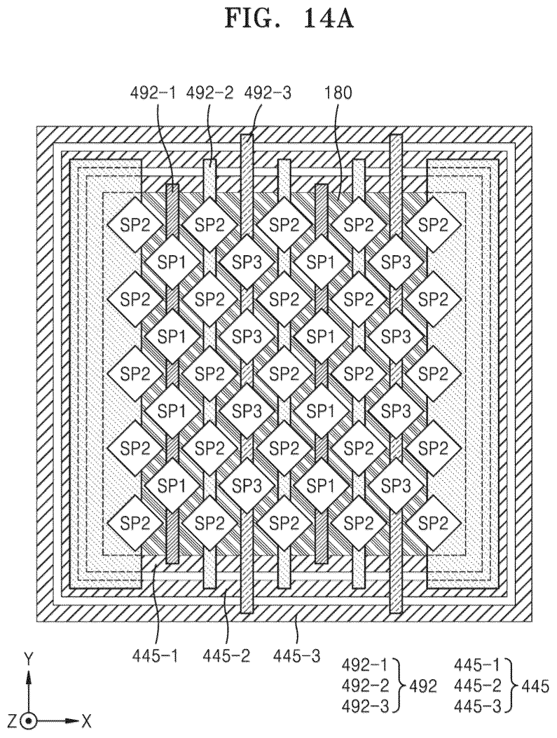

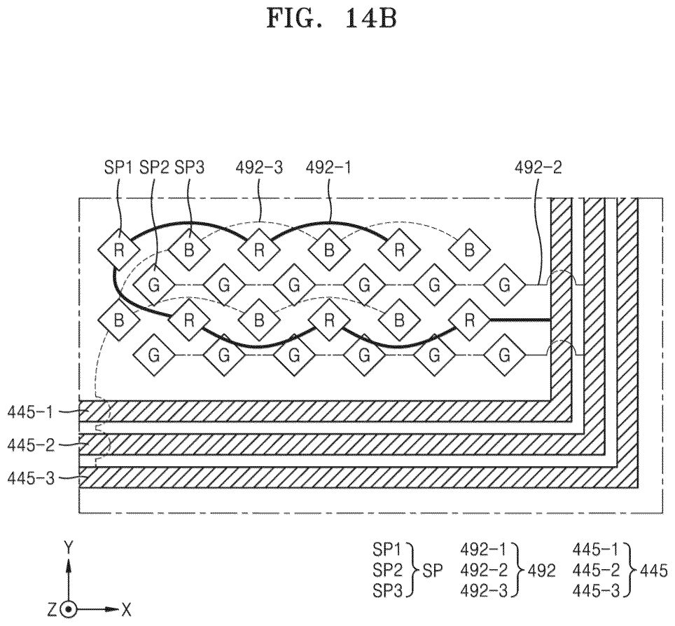

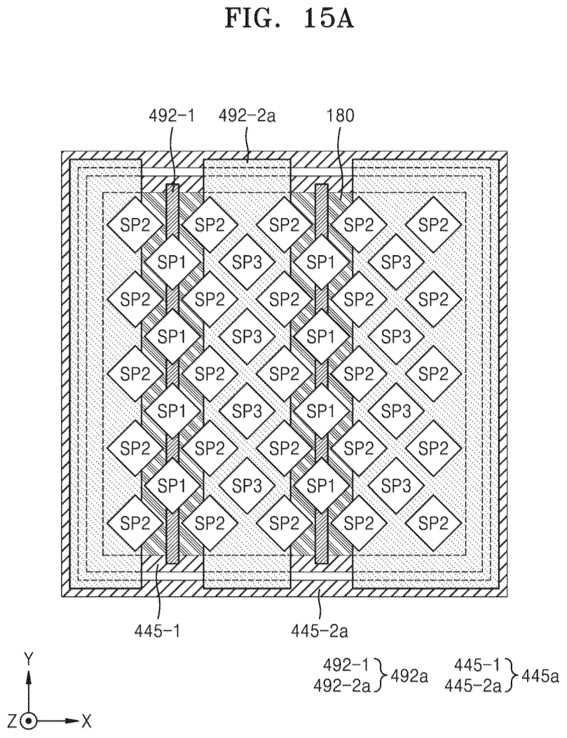

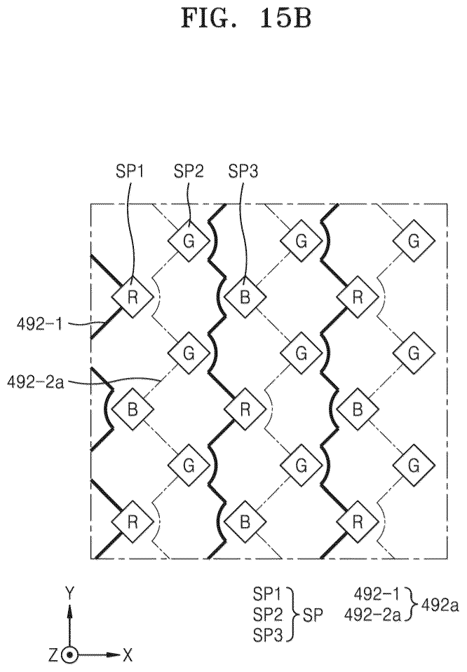

FIG. 13 is an enlarged plan view of a portion corresponding to a portion indicated by “EX2” of FIG. 1. FIG. 14A is a plan view illustrating a display device according to one or more embodiments, and FIG. 14B is a view schematically illustrating a region of the display device of FIG. 14A which corresponds to a region A of FIG. 2. FIG. 15A is a plan view illustrating a display device according to one or more embodiments, and FIG. 15B is a view schematically illustrating a connection relationship between a plurality of sub-pixels and wires of the display device of FIG. 15A. FIG. 14B schematically illustrates an electrical connection relationship between sub-pixels SP, wires, and conductive layers 445. The number of sub-pixels illustrated in FIGS. 14A and 15A is an example for the sake of convenience of description, and the number of sub-pixels arranged in a pixel array may be changed. FIGS. 13 to 15B illustrate, for example, first, second, and third sub-pixels SP1, SP2, and SP3 that are arranged in a pentile pattern.

Referring to FIGS. 13 to 15B, unlike the plurality of sub-pixels SP arranged in a checkerboard pattern in the region EX2 of FIG. 1, a pixel PXa in a region EX2a of FIG. 13 may include a plurality of sub-pixels SP arranged in a diamond shape. A pixel array 410a may include a plurality of pixels PXa, and the plurality of pixels PXa may include second sub-pixels SP2 and third sub-pixels SP3 arranged in a first diagonal direction, and first sub-pixels SP1 and second sub-pixel SP2 separated from each other in a second diagonal direction intersecting the first diagonal direction and arranged in the first diagonal direction.

As described with reference to FIGS. 11A and 11B, in FIGS. 14A and 14B, the first sub-pixels SP1 may be electrically connected to each other by a first wire 492-1 and may be electrically connected to a first conductive layer 445-1. Also, the second sub-pixels SP2 may be electrically connected to each other by a second wire 492-2 and may be electrically connected to a second conductive layer 445-2. In addition, the third sub-pixels SP3 may be electrically connected to each other by a third wire 492-3 and may be electrically connected to a third conductive layer 445-3.

Also, as described with reference to FIGS. 12A and 12B, in FIGS. 15A and 15B, the first sub-pixels SP1 may be electrically connected to each other by the first wire 492-1 and may be electrically connected to the first conductive layer 445-1. Also, the plurality of second sub-pixels SP2 may be electrically connected to each other by the second wire 492-2a and may be electrically connected to the second conductive layer 445-2a, and the third sub-pixels SP3 may be electrically connected to each other by the second wire 492-2a and may be electrically connected to the second conductive layer 445-2a.

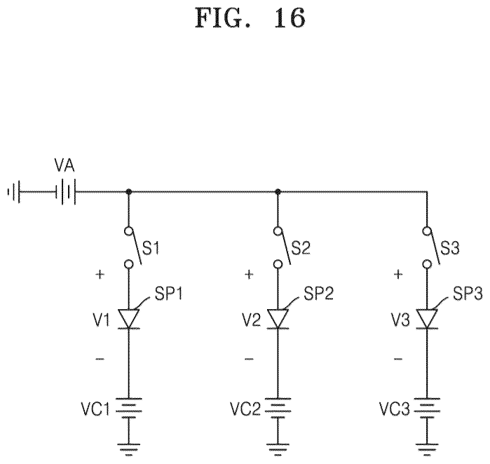

FIGS. 16 to 18 are circuit diagrams briefly illustrating display devices according to embodiments. Descriptions are made with reference to FIGS. 1 to 15B together.

Referring to FIG. 16, an anode voltage VA and first, second, and third switches S1, S2, and S3 may be arranged at anodes of first, second, and third sub-pixels SP1, SP2, and SP3, and first, second, and third cathode voltages VC1, VC2, and VC3 may be arranged at cathodes of the first, second, and third sub-pixels SP1, SP2, and SP3.

The first switch S1 may be arranged at the anode of the first sub-pixel SP1, and the first cathode voltage VC1 may be arranged at the cathode of the first sub-pixel SP1. A first voltage V1 may be applied to the first sub-pixel SP1, and the first voltage V1 may be a voltage difference between the anode voltage VA and the first cathode voltage VC1.

The second switch S2 may be arranged at the anode of the second sub-pixel SP2, and the second cathode voltage VC2 may be arranged at the cathode of the second sub-pixel SP2. A second voltage V2 may be applied to the second sub-pixel SP2, and the second voltage V2 may be a voltage difference between the anode voltage VA to the second cathode voltage VC2.

The third switch S3 may be arranged at the anode of the third sub-pixel SP3, and the third cathode voltage VC3 may be arranged at the cathode of the third sub-pixel SP3. A third voltage V3 may be applied to the third sub-pixel SP3, and the third voltage V3 may be a voltage difference between the anode voltage VA to the third cathode voltage VC3.

As illustrated in FIG. 16, the same anode voltage VA may be applied to the anodes of the first, second, and third sub-pixels SP1, SP2, and SP3. This may be referred to as a common anode type. Also, by applying different cathode voltages to the cathodes of the first, second, and third sub-pixels SP1, SP2, and SP3, driving voltages of the first, second, and third sub-pixels SP1, SP2, and SP3 may be controlled differently. By independently controlling the driving voltages of the first, second, and third sub-pixels SP1, SP2, and SP3, heat generated by the display devices 400, 400a, and 400b may be reduced, lifespans of the display devices 400, 400a, and 400b may be extended, and efficiencies of the display devices 400, 400a, and 400b may be increased.

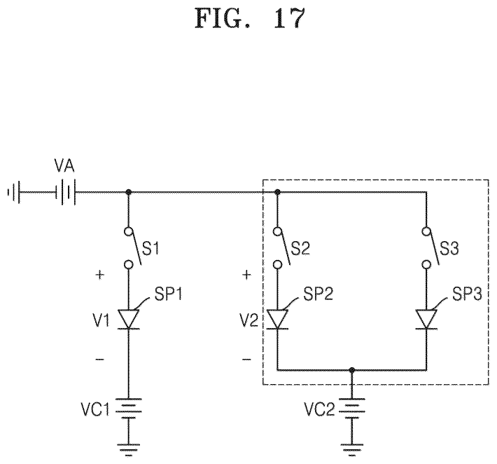

Referring to FIG. 17, an anode voltage VA and first, second, and third switches S1, S2, and S3 may be arranged at anodes of first, second, and third sub-pixels SP1, SP2, and SP3, and first and second cathode voltages VC1 and VC2 may be arranged at cathodes of the first, second, and third sub-pixels SP1, SP2, and SP3.

The first switch S1) may be arranged at the anode of the first sub-pixel SP1, and the first cathode voltage VC1 may be arranged at the cathode of the first sub-pixel SP1. A first voltage V1 may be applied to the first sub-pixel SP1, and the first voltage V1 may be a voltage difference between the anode voltage VA and the first cathode voltage VC1.

The second switch S2 may be arranged at the anode of the second sub-pixel SP2, the third switch S3 may be arranged at the anode of the third sub-pixel SP3, and the second cathode voltage VC2 may be arranged at the cathode of the second sub-pixel SP2 and the cathode of the third sub-pixel SP3. A second voltage V2 may be applied to the second sub-pixel SP2 and the third sub-pixel SP3, and the second voltage V2 may be a voltage difference between the anode voltage VA and the second cathode voltage VC2. Therefore, the same voltage may be applied to the second sub-pixel SP2 and the third sub-pixel SP3.

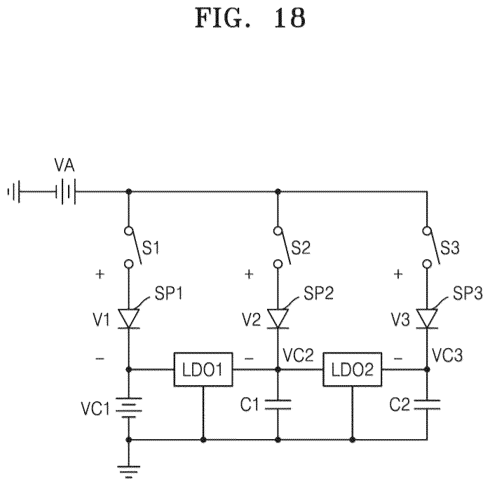

Referring to FIG. 18, an anode voltage VA and first, second, and third switches S1, S2, and S3 may be arranged at anodes of first, second, and third sub-pixels SP1, SP2, and SP3, and first, second, and third cathode voltages may be arranged at cathodes of the first, second, and third sub-pixels SP1, SP2, and SP3.

The first switch S1 may be arranged at the anode of the first sub-pixel SP1, and the first cathode voltage VC1 may be arranged at the cathode of the first sub-pixel SP1. A first voltage V1 may be applied to the first sub-pixel SP1, and the first voltage V1 may be a voltage difference between the anode voltage VA and the first cathode voltage VC1.

The second switch S2 may be arranged at the anode of the second sub-pixel SP2, and a first capacitor C1 may be arranged at the cathode of the second sub-pixel SP2. The first capacitor Cl may remove noise such that a circuit may be driven stably. A first low drop out (LDO) LDO1 may be arranged between the cathode of the first sub-pixel SP1 and the cathode of the second sub-pixel SP2. The first LDO LDO1 may drop the first cathode voltage VC1. Therefore, the second cathode voltage VC2, which is a voltage dropped from the first cathode voltage VC1, may be applied to the cathode of the second sub-pixel SP2. A second voltage V2 may be applied to the second sub-pixel SP2, and the second voltage V2 may be a voltage difference between the anode voltage VA and the second cathode voltage VC2.

The third switch S3 may be arranged at the anode of the third sub-pixel SP3, and a second capacitor C2 may be arranged at the cathode of the third sub-pixel SP3. The second capacitor C2 may remove noise such that the circuit may be driven stably. A second LDO LDO2 may be arranged between the cathode of the second sub-pixel SP2 and the cathode of the third sub-pixel SP3. The second LDO LDO2 may drop the second cathode voltage VC2. The third cathode voltage VC3, which is a voltage dropped from the second cathode voltage VC2, may be applied to the cathode of the third sub-pixel SP3. A third voltage V3 may be applied to the third sub-pixel SP3, and the third voltage V3 may be a voltage difference between the anode voltage VA and the third cathode voltage VC3.

In FIGS. 16 to 18, wires electrically connecting the first, second, and third sub-pixels SP1, SP2, and SP3 to the first, second, and third cathode voltages VC1, VC2, and VC3 may be the first, second, and third wires 492-1, 492-2, and 492-3 described with reference to FIGS. 4 to 7. Also, the first, second, and third cathode voltages VC1, VC2, and VC3 may be power supply voltages electrically connected to the first, second, and third conductive layers 445-1, 445-2, and 445-3.

Although a method for controlling voltages applied to the first, second, and third sub-pixels SP1, SP2, and SP3 is described above, the disclosure is not limited thereto. It is natural that various methods for controlling the voltage applied to the first, second, and third sub-pixels SP1, SP2, and SP3 may be used.

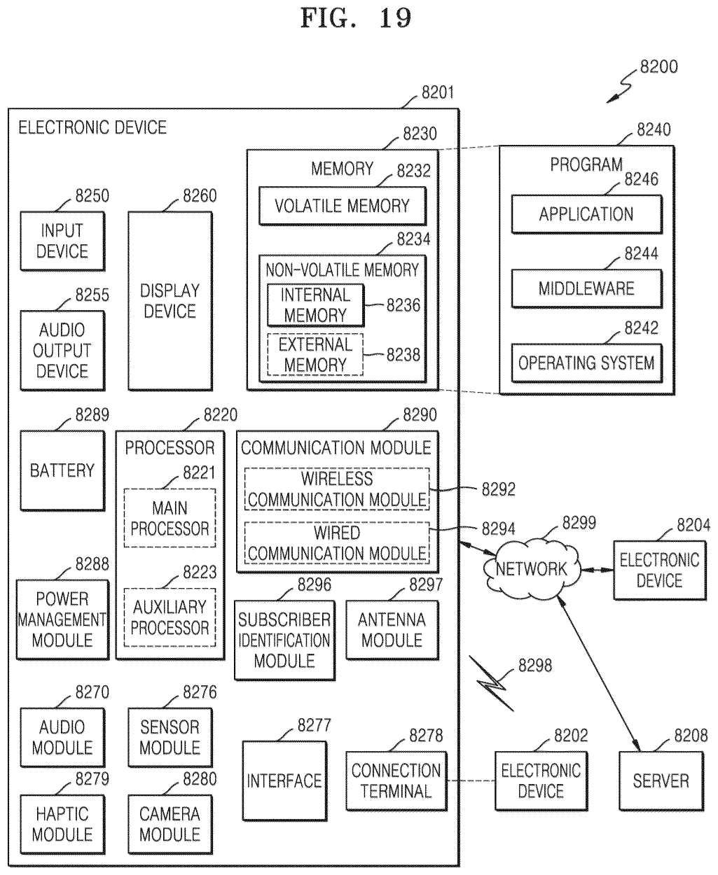

FIG. 19 is a block diagram of an electronic device including a display device according to one or more embodiments.

Referring to FIG. 19, an electronic device 8201 may be provided in a network environment 8200. In the network environment 8200, the electronic device 8201 may communicate with another electronic device 8202 through a first network 8298 (such as a short-range wireless communication network) or may communicate with another electronic device 8204 and/or a server 8208 through a second network 8299 (such as a long-range wireless communication network). The electronic device 8201 may communicate with the electronic device 8204 through the server 8208. The electronic device 8201 may include a processor 8220, a memory 8230, an input device 8250, an audio output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some components may be omitted from the electronic device 8201 or other components may be added to the electronic device 8201. Some components may be included in a single integrated circuit. For example, the sensor module 8276 (such as a fingerprint sensor, an iris sensor, or an ambient light sensor) may be embedded in the display device 8260 (such as a display).

The processor 8220 may execute software (such as a program 8240) to control one or more other components (such as hardware, software components, and so on) of the electronic device 8201 connected to the processor 8220, and perform various data processing or calculations. In order to perform the data processing or calculations, the processor 8220 may load commands and/or data received from other components (such as the sensor module 8276, the communication module 8290, and so on) into a volatile memory 8232, process the commands and/or data stored in the volatile memory 8232, and store resulting data in the nonvolatile memory 8234. The processor 8220 may include a main processor 8221 (such as a central processing unit, an application processor, or so on) and an auxiliary processor 8223 (such as a graphics processing unit, an image signal processor, a sensor hub processor, a communication processor, or so on) that may operate independently of or together with the main processor 8221. The auxiliary processor 8223 may use less power than the main processor 8221 and may perform specialized functions.

The auxiliary processor 8223 may control functions and/or states related to some components (such as the display device 8260, the sensor module 8276, and the communication module 8290) of the electronic device 8201 in place of the main processor 8221 while the main processor 8221 is in an inactive state (sleep state) or together with the main processor 8221 while the main processor 8221 is in an active state (an application execution state). The auxiliary processor 8223 (such as an image signal processor, a communication processor, or so on) may also be implemented as some of other functionally related components (such as the camera module 8280, the communication module 8290, and so on).

The memory 8230 may store various types of data required by components (the processor 8220, the sensor module 8276, and so on) of the electronic device 8201. The data may include, for example, software (the program 8240 and so on) and input data and/or output data for commands related thereto. The memory 8230 may include the volatile memory 8232 and/or the nonvolatile memory 8234.

The program 8240 may be stored as software in the memory 8230 and may include an operating system 8242, middleware 8244, and/or an application 8246.

The input device 8250 may receive commands and/or data to be used by components (processor 8220 and so on) of the electronic device 8201 from an external source (a user or so on) of the electronic device 8201. The input device 8250 may include a remote controller, a microphone, a mouse, a keyboard, and/or a digital pen (such as a stylus pen).

The audio output device 8255 may output audio signals to the outside of the electronic device 8201. The audio output device 8255 may include a speaker and/or a receiver. The speaker may be used for general purposes such as multimedia playback or recording playback, and the receiver may be used to receive incoming calls. The receiver may be incorporated as a part of the speaker or may be implemented by a separate and independent device.

The display device 8260 may visually provide information to the outside of the electronic device 8201. The display device 8260 may include a display, a holographic device, or a projector and a control circuit for controlling a corresponding device. The display device 8260 may include the display device 400, 400a, or 400b illustrated in FIGS. 1, 10, and 13. The display device 8260 may include touch circuitry configured to detect a touch, and/or sensor circuitry (such as a pressure sensor) configured to measure the intensity of a force generated by the touch.

The audio module 8270 may convert audio into an electrical signal, or vice versa. The audio module 8270 may acquire sound through the input device 8250, or output sound through a speaker and/or a headphone of the audio output device 8255 and/or another electronic device (such as the electronic device 8202) directly or wirelessly connected to the electronic device 8201.

The sensor module 8276 may detect operation states (power, temperature, and so on) of the electronic device 8201 or an external environment state (such as a user's state) and generate an electrical signal and/or a data value corresponding to the detected state. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more designated protocols that may be used to directly or wirelessly connect the electronic device 8201 to another electronic device (such as the electronic device 8202). The interface 8277 may include a high definition multimedia interface (HDMI), a Universal Serial Bus (USB) interface, a secure digital (SD) card interface, and/or an audio interface.

A connection terminal 8278 may include a connector that may physically connect the electronic device 8201 to another electronic device (such as the electronic device 8202). The connection terminal 8278 may include an HDMI connector, a USB connector, an SD card connector, and/or an audio connector (such as a headphone connector).

The haptic module 8279 may convert an electrical signal into a mechanical stimulus (such as vibration, movement, or so on) or an electrical stimulus that may be perceived by a user through a tactile or kinesthetic sense. The haptic module 8279 may include a motor, a piezoelectric element, and/or an electrical stimulation device.

The camera module 8280 may capture still images and moving images. The camera module 8280 may include a lens assembly including one or more lenses, image sensors, image signal processors, and/or flashes. The lens assembly included in the camera module 8280 may collect light emitted from a subject that is a target of image capture.

The power management module 8288 may manage the power supplied to the electronic device 8201. The power management module 8288 may be implemented as a part of a power management integrated circuit (PMIC).

The battery 8289 may supply power to components of the electronic device 8201. The battery 8289 may include a non-rechargeable primary battery, a rechargeable secondary battery, and/or a fuel cell.

The communication module 8290 may support the establishment of a direct (wired) communication channel and/or a wireless communication channel between the electronic device 8201 and other electronic devices (such as the electronic device 8202, the electronic device 8204, the server 8208, and so on), and the performance of communication through the established communication channel. The communication module 8290 may operate independently from the processor 8220 (such as an application processor) and may include one or more communication processors that support direct communication and/or wireless communication. The communication module 8290 may include a wireless communication module 8292 (a cellular communication module, a short-range wireless communication module, a global navigation satellite system (GNSS) communication module, and/or a wired communication module 8294 (such as a local area network (LAN) communication module, a power line communication module, or so on). Among the communication modules, a corresponding communication module may communicate with another electronic device through a first network 8298 (a short-range communication network, such as Bluetooth, WiFi Direct, or infrared data association (IrDA)) or a second network 8299 (a long-range communication network, such as a cellular network, the Internet, or a computer network (a LAN, a wide area network (WAN), or so on)). The various types of communication modules may be integrated into one component (such as a single chip) or implemented as multiple separate components (multiple chips). The wireless communication module 8292 may identify and authenticate the electronic device 8201 within a communication network, such as the first network 8298 and/or the second network 8299 by using subscriber information (such as an international mobile subscriber identity (IMSI)) stored in the subscriber identification module 8296.

The antenna module 8297 may transmit or receive signals and/or power to or from the outside (such as other electronic devices). An antenna may include a radiator including a conductive pattern formed on a substrate (such as a printed circuit board (PCB)). The antenna module 8297 may include one or more antennas. When multiple antennas are included in the communication module 8290, the communication module 8290 may select an antenna suitable for a communication method used for a communication network, such as the first network 8298 and/or the second network 8299, from among the multiple antennas. Signals and/or power may be transmitted or received between the communication module 8290 and other electronic devices through the selected antenna. In addition to the antenna, other components (such as a radio frequency integrated circuit (RFIC)) may be included in the antenna module 8297.

Some of components of the electronic device 8201 may be connected to each other through a communication method (such as a bus, general purpose input and output (GPIO), a serial peripheral interface (SPI), a mobile industry processor interface (MIPI)) between peripheral devices and may exchange signals (such as commands, data, and so on).

The commands or data may be transmitted or received between the electronic device 8201 and the external electronic device 8204 through the server 8208 connected to the second network 8299. Other electronic devices 8202 and 8204 may be the same device as the electronic device 8201 or different devices from the electronic device 8201. All or part of operations performed by the electronic device 8201 may be performed by one or more of the electronic devices 8202, 8204, and 8208. For example, when the electronic device 8201 needs to perform a function or service, the electronic device 8201 may request one or more other electronic devices to perform the function or part or all of the service, instead of performing the function or service itself. One or more other electronic devices that receive a request may perform additional function or service related to the request and transmit a result of the performance to the electronic device 8201. For this purpose, cloud computing, distributed computing, and/or client-server computing technologies may be used.

The electronic device 8201 may be applied to various devices. Various components of the electronic device 8201 may be appropriately changed depending on functions of the electronic device 8201, and components suitable for performing the functions of the electronic device 8201 may be added to the electronic device 8201. Hereinafter, application examples of the electronic device 8201 are described.

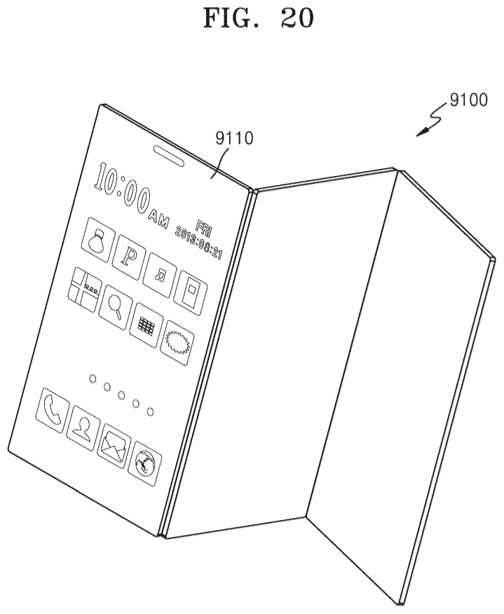

FIG. 20 is a view illustrating one or more embodiments of a mobile device as an application example of an electronic device. A mobile device 9100 may include a display device 9110. The display device 9110 may include the display devices 400, 400a, and 400b respectively illustrated in FIG. 1, FIG. 10, and FIG. 13. The display device 9110 may have a foldable structure, for example, a multi-foldable structure.

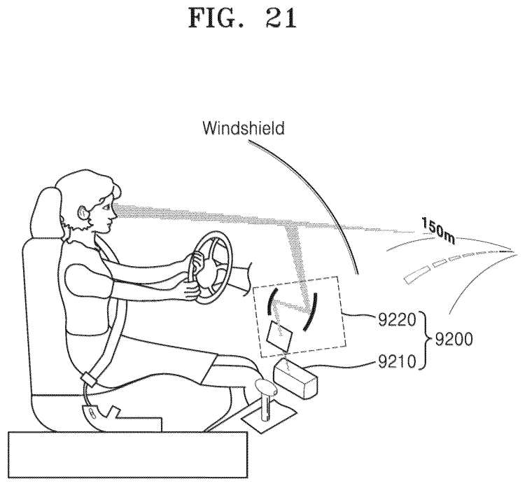

FIG. 21 is a view illustrating one or more embodiments of a head-up display device for a vehicle as an application example of an electronic device. A head-up display device 9200 for a vehicle may include a display 9210 provided in a region of the vehicle, and an optical path change member 9220 that changes an optical path such that a driver may view an image generated by the display 9210. The display 9210 may include the display devices 400, 400a, and 400b respectively illustrated in FIG. 1, FIG. 10, and FIG. 13.

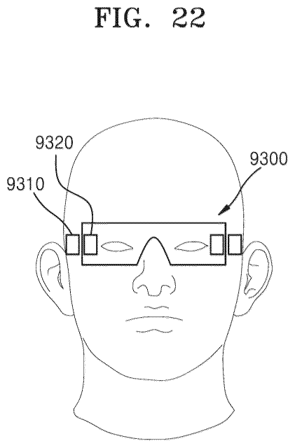

FIG. 22 is a view illustrating one or more embodiments of augmented reality glasses or virtual reality glasses as an application example of an electronic device. An augmented reality glasses (or a virtual reality glasses) 9300 may include a projection system 9310 that forms an image, and an element 9320 that guides an image from the projection system 9310 to enter a user's eyes. The projection system 9310 may include the display devices 400, 400a, and 400b respectively illustrated in FIG. 1, FIG. 10, and FIG. 13.

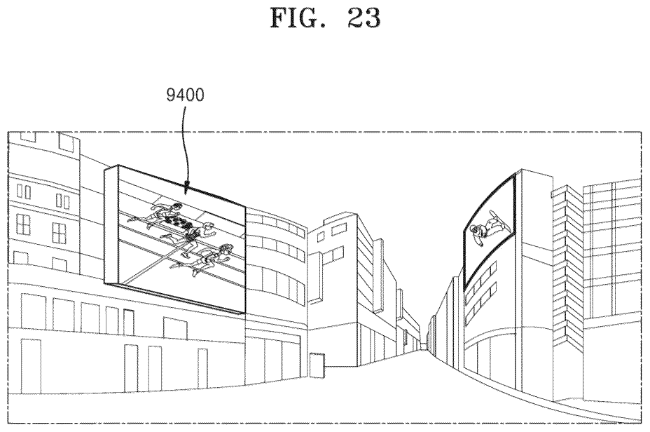

FIG. 23 is a view illustrating one or more embodiments of a large signage as an application example of an electronic device. A signage 9400 may include the display devices 400, 400a, and 400b respectively illustrated in FIG. 1, FIG. 10, and FIG. 13. The signage 9400 may be used for outdoor advertisement using a digital information display and may control content of advertisement and so on through a communication network. The signage 9400 may be implemented through, for example, the electronic device described with reference to FIG. 19.

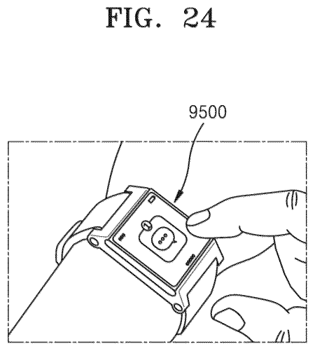

FIG. 24 is a view illustrating one or more embodiments of a wearable display as an application example of an electronic device. A wearable display 9500 may include the display devices 400, 400a, and 400b respectively illustrated in FIG. 1, FIG. 10, and FIG. 13. The wearable display 9500 may be implemented through the electronic device described with reference to FIG. 19.

The display devices 400, 400a, and 400b respectively illustrated in FIG. 1, FIG. 10, and FIG. 13 may be applied to various products, such as rollable TVs and stretchable displays, in addition to the electronic devices illustrated above.

As described above, although the disclosure is described with reference to the embodiments illustrated in the drawings, these are merely examples, and those skilled in the art will understand that various modifications and equivalent other embodiments may be made therefrom. Therefore, the true technical protection scope of the disclosure should be determined by the technical idea of the appended patent claims.

While the disclosure has been particularly shown and described with reference to embodiments thereof, it will be understood that various changes in form and details may be made therein without departing from the spirit and scope of the following claims.

1. A display device comprising:
a substrate;
first sub-pixels;
second sub-pixels;
third sub-pixels, wherein the first sub-pixels, the second sub-pixels, and the third sub-pixels are separated in a horizontal direction;
a first wire electrically connecting the first sub-pixels; and
a second wire electrically connecting the second sub-pixels, wherein the first wire is electrically separated from the second wire.

2. The display device of claim 1, further comprising:
a third wire electrically connecting the third sub-pixels,
wherein the first, second, and third wires are electrically separated.

3. The display device of claim 1, wherein the second wire electrically connects the second sub-pixels to the third sub-pixels.

4. The display device of claim 1,
wherein the first wire is electrically connected to a first conductive layer,
wherein the second wire is electrically connected to a second conductive layer, and
wherein the first conductive layer is electrically separated from the second conductive layer.

5. The display device of claim 4, wherein the first conductive layer is separated from the second conductive layer in the horizontal direction.

6. The display device of claim 1, wherein a cross-sectional area of the first wire is different from a cross-sectional area of the second wire.

7. The display device of claim 1, wherein the first sub-pixels, the second sub-pixels, and the third sub-pixels are in a pentile pattern.

8. A display device comprising:
a substrate;
a first sub-pixel;
a second sub-pixel;
a third sub-pixel, wherein the first sub-pixel, the second sub-pixel, and the third sub-pixel are separated in a horizontal direction;
a first conductive layer configured to receive a first voltage;
a second conductive layer configured to receive a second voltage different from the first voltage;
a first wire electrically connecting the first sub-pixel to the first conductive layer; and
a second wire electrically connecting the second sub-pixel to the second conductive layer,
wherein the first wire is electrically separated from the second wire, and
wherein the first conductive layer is electrically separated from the second conductive layer.

9. The display device of claim 8, further comprising:
a third conductive layer configured to receive a third voltage different from the first voltage and the second voltage; and
a third wire electrically connecting the third sub-pixel to the third conductive layer,
wherein the third conductive layer is electrically separated from the first conductive layer and the second conductive layer.

10. The display device of claim 8, wherein the second wire electrically connects the third sub-pixel to the second conductive layer.

11. The display device of claim 8, wherein
the first voltage is applied to the first conductive layer, and
the second voltage is dropped from the first voltage.

12. The display device of claim 8, wherein the first sub-pixel is configured to receive a voltage, and the second sub-pixel is configured to receive another voltage different from the voltage.

13. The display device of claim 8, wherein a cathode of the first sub-pixel is configured to receive a voltage, and a cathode of the second sub-pixel is configured to receive another voltage different from the voltage.

14. The display device of claim 8, wherein a number of electrically separated wires is based on a number of electrically separated conductive layers.

15. A display device comprising:
a circuit substrate comprising a drive circuit; and
a pixel array on the circuit substrate, the pixel array comprising:
a first sub-pixel;
a second sub-pixel;
a third sub-pixel;
a first conductive base semiconductor layer comprising a main surface and a back surface opposite to the main surface;
a plurality of semiconductor light-emitting structures on the main surface of the first conductive base semiconductor layer and separated in a horizontal direction parallel to the main surface, the plurality of semiconductor light-emitting structures comprising a first conductive semiconductor layer, an active layer, and a second conductive semiconductor layer sequentially stacked in a vertical direction perpendicular to the main surface;
a first electrode between adjacent identical sub-pixels, the first electrode comprising a metal layer passing through the first conductive base semiconductor layer in the vertical direction;
a separation layer between the first sub-pixel and the second sub-pixel which are adjacent, the separation layer comprising an insulating layer passing through the first conductive base semiconductor layer in the vertical direction;
a reflective structure covering sidewalls of the plurality of semiconductor light-emitting structures;
a plurality of second electrodes passing through the reflective structure in the vertical direction; and
a plurality of microlenses on the back surface of the first conductive base semiconductor layer and overlapping the plurality of semiconductor light-emitting structures in the vertical direction.

16. The display device of claim 15, wherein the first electrode is between the second sub-pixel and the third sub-pixel.

17. The display device of claim 15, wherein the separation layer is between the second sub-pixel and the third sub-pixel.

18. The display device of claim 15, further comprising:
a plurality of conductive layers around the pixel array and electrically connected to the first electrode,
wherein the plurality of conductive layers are separated in the horizontal direction.

19. The display device of claim 18, wherein the plurality of conductive layers have a square ring shape.

20. The display device of claim 15, wherein a vertical level of an upper surface of the first electrode is higher than a vertical level of an upper surface of the separation layer.

21. (canceled)
